(19) United States
(12) Patent Application Publication
(10) Pub. No.: US 2013/0075800 A1
(43) Pub. Date: Mar. 28, 2013

(54) SEMICONDUCTOR DEVICE MANUFACTURING METHOD, SEMICONDUCTOR DEVICE AND SUBSTRATE PROCESSING APPARATUS

(71) Applicant: HITACHI KOKUSAI ELECTRIC INC., Tokyo (JP)

(72) Inventors: Sadayoshi Horii, Toyama-shi (JP); Hideharu Itatani, Toyama-shi (JP)

(73) Assignee: HITACHI KOKUSAI ELECTRIC INC., Tokyo (JP)

(21) Appl. No.: 13/625,875

(22) Filed: Sep. 25, 2012

(30) Foreign Application Priority Data
Sep. 26, 2011 (JP) 2011-208417
Aug. 28, 2012 (JP) 2012-187753

(51) Int. Cl. H01L 29/94; H01L 21/20

(52) U.S. Cl. 257/296; 438/381; 118/715; 257/E21.008; 257/E29.342

(57) ABSTRACT

A semiconductor device manufacturing method includes loading a substrate to a processing chamber, a gate insulating film or a capacitor insulating film being formed on a surface of the substrate; forming an electrode, which includes a conductive oxide film and to which an additive that modulates a work function of the conductive oxide film is added, on the substrate; and unloading the substrate, on which the electrode is formed, from the processing chamber.

### CROSS-REFERENCE TO RELATED APPLICATION

This application claims priority under 35 USC 119 from Japanese Patent Application No. 2011-208417 filed on Sep. 26, 2011 and Japanese Patent Application No. 2012-187753 filed on Aug. 28, 2012, the disclosures of which are incorporated by reference herein.

### BACKGROUND

### Related Art

The present invention relates to a manufacturing method of a semiconductor device, a semiconductor device and a substrate processing apparatus.

Along with higher integration and higher performance in regard to a MOSFET (Metal Oxide Semiconductor Field Effect Transistor), application of a High-k/Metal gate structure that uses an insulating film having a high dielectric constant (High-k) as a gate insulating film has been reviewed. In CMOS devices, a gate electrode of a metallic film having a work function of approximately 4.8 to 5.1 eV is preferable for a pMOS, and Ru or Pt has been nominated as a candidate.

In addition, in accordance with a higher dielectric constant of a capacitor insulating film according to higher integration of a DRAM (Dynamic Random Access Memory) cell, TiN, Ru, or the like has been reviewed as a capacitor electrode material of the DRAM. Commonly, an electrode with a high work function is ideally used for an electrode of a capacitor portion of the DRAM from a viewpoint of reduction in a leak current, but an electrode, which is a metallic film that may be formed cheaply in consideration of a cost aspect and which is also capable of sufficiently securing band offset with an insulating film, is selected. For example, in a case where an HfO₂ film or a ZrO₂ film that is an insulating film having a wide band gap, TiN with a work function of approximately 4.6 eV is used. On the other hand, for a film of TiO₂ or Nb₂O₅ with a narrow band gap, a TiN film is not used, and a noble metal, which is expensive, such as Ru and Pt with a high work function of approximately 5.1 eV has been nominated as a candidate.

However, in a case where the noble metal such as Ru and Pt is used as the electrode material, there are problems in that the material is expensive, film formation is very difficult, and the like, and thus the noble metal has not come into practical use. In addition, in a case where a relatively cheap metallic film of Ni, Co, or the like with a high work function is used as an electrode, for example, for a lower electrode of a capacitor, since the lower electrode is exposed to an oxidizing atmosphere during formation of an insulating film that is formed thereon, the Ni film or Co film that is easily oxidized becomes an insulating film, and the electrostatic capacitance thereof is connected to an electrostatic capacitance of a capacitor insulating film in series, thereby leading to a decrease in total electrostatic capacitance. In addition, in a case where the Ni film or the Co film is used as an upper electrode of a capacitor or a gate electrode of the MOSFET, since an insulating film containing oxygen is present under the upper electrode or the gate electrode, Ni or Co comes into contact with oxygen at a high temperature and is oxidized during forming an electrode. Therefore, the Ni film or Co film becomes an insulating film, thereby leading to a decrease in total electrostatic capacitance or an increase in EOT (Equivalent Oxide Thickness), similarly to the lower electrode.

Japanese Patent Application Laid-Open (JP-A) No. 2011-142226 discloses that an electrode with necessary work function and oxidation resistance is provided with low manufacturing cost by using a laminated structure in which a TiN thin film having oxidation resistance is inserted between a material such as Ni and Co that has low oxidation resistance and an insulating film.

However, the present inventors have found that when TiN is inserted in such a manner, the high work function of Ni or Co may be weakened. In addition, TiN has oxidation resistance, but the outermost surface thereof is certainly oxidized, and thus a decrease in electrostatic capacitance is recognized.

### SUMMARY

An object of the present invention is to provide a method of manufacturing a semiconductor device provided with an electrode that is excellent in oxidation resistance and is capable of preventing or suppressing deterioration of a conductive property and a work function, a semiconductor device, and a substrate processing apparatus.

According to an aspect of the present invention, there is provided a semiconductor device manufacturing method including:

loading a substrate to a processing chamber, a gate insulating film or a capacitor insulating film being formed on the substrate;

forming an electrode, which includes a conductive oxide film and to which an additive that modulates a work function of the conductive oxide film is added, on the substrate; and

unloading the substrate, on which the electrode is formed, from the processing chamber.

According to another aspect of the present invention, there is provided a semiconductor device including:

a gate insulating film or a capacitor insulating film that is formed on a substrate; and

an electrode including a conductive oxide film that is formed to come into contact with the gate insulating film or the capacitor insulating film,

wherein an additive that modulates a work function of the conductive oxide film is included in the conductive oxide film.

According to a still another aspect of the present invention, there is provided a substrate processing apparatus including:

a processing chamber that accommodates a substrate, a gate insulating film or a capacitor insulating film being formed on a surface of the substrate;

a raw material gas supply system that supplies plural raw material gases to the processing chamber; and

a controller that controls the raw material gas supply system to form an electrode, which includes a conductive oxide film to which an additive modulating a work function of the conductive oxide film is added, on the substrate by exposing the substrate to the plural raw material gases.

### BRIEF DESCRIPTION OF THE DRAWINGS

Exemplary embodiments of the present invention will be described in detail based on the following figures, wherein:

FIG. 1 is a configuration diagram schematically illustrating a gas supply system that is provided to a substrate processing apparatus according to first and second preferred embodiments of the present invention;

FIG. 2 is a cross-sectional configuration diagram schematically illustrating the substrate processing apparatus according to the first and second preferred embodiments of the present invention during wafer processing;

FIG. 3 is a cross-sectional configuration diagram schematically illustrating the substrate processing apparatus according to the first and second preferred embodiments of the present invention during wafer conveyance;

FIGS. 4A and 4B are flow diagrams of an electrode forming process according to the first and second preferred embodiments of the present invention;

FIGS. 5A and 5B are cross-sectional configuration diagrams schematically illustrating a gate electrode according to the first preferred embodiment of the present invention, in which FIG. 5A is a diagram illustrating the gate electrode in which a film of a laminated structure, in which plural ZnO films and plural Ga₂O₃ films are alternately laminated, is formed, on a gate insulating film, and FIG. 5B is a diagram illustrating the gate electrode in which a GZO (Ga-doped ZnO) film, in which ZnO and Ga₂O₃ are mixed with each other, and which contains Ga₂O₃ as an additive in ZnO, is formed on the gate insulating film;

FIGS. 6A and 6B are cross-sectional configuration diagrams schematically illustrating a capacitor electrode according to the second preferred embodiment of the present invention, in which FIG. 6A is a diagram illustrating the capacitor electrode in which a film of a laminated structure, in which plural ZnO films and plural Ga₂O₃ films are alternately laminated, is formed as a lower electrode, and FIG. 6B is a diagram illustrating the capacitor electrode in which a GZO film, in which ZnO and Ga₂O₃ are mixed with each other and which contains Ga₂O₃ as an additive in ZnO, is formed on a gate insulating film;

FIG. 7 is a longitudinal cross-sectional configuration diagram schematically illustrating a processing furnace of the substrate processing apparatus according to a third preferred embodiment of the invention;

FIG. 8 is a transverse cross-sectional configuration diagram schematically illustrating the processing furnace shown in FIG. 7;

FIGS. 9A and 9B are flow diagrams of an electrode forming process according to the third preferred embodiment of the present invention; and

FIG. 10 is a timing chart of the electrode forming process according to the third preferred embodiment of the present invention.

### DETAILED DESCRIPTION

Next, preferred embodiments of the invention will be described in detail with reference to the attached drawings.

### First Embodiment

### (1) Configuration of Substrate Processing Apparatus

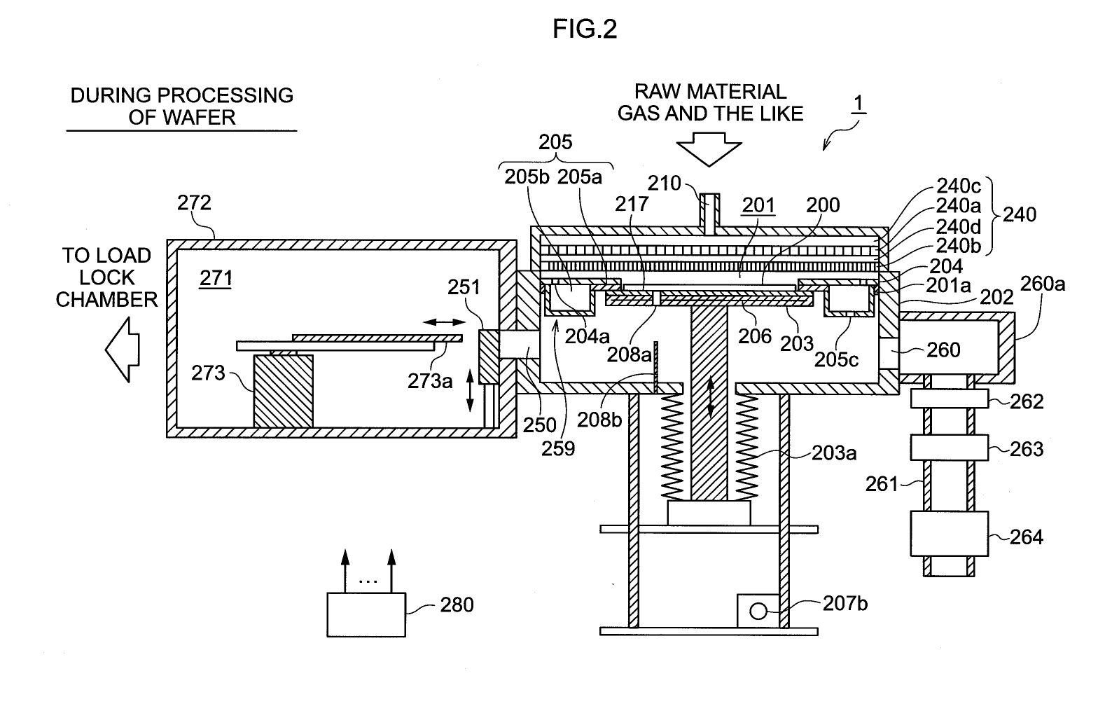

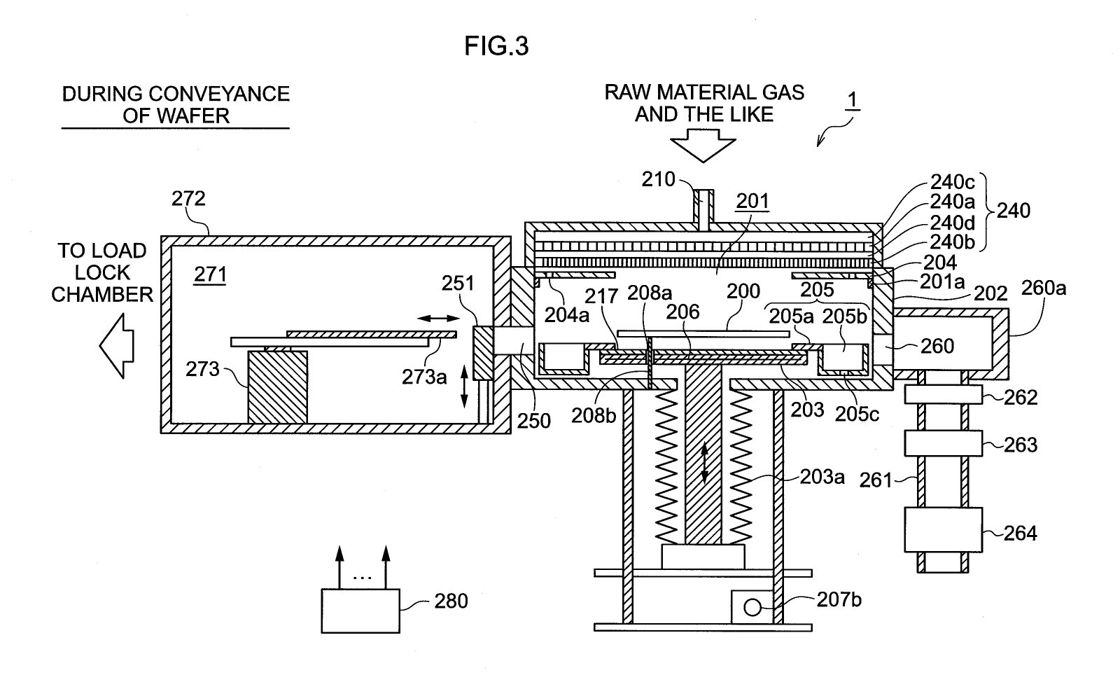

First, description will be made with respect to a configuration of a substrate processing apparatus 1 according to first and second preferred embodiments of the present invention with reference to FIGS. 2 and 3. FIG. 2 shows a cross-sectional configuration diagram illustrating the substrate processing apparatus 1 according to the first and second preferred embodiments of the present invention during wafer processing, and FIG. 3 shows a cross-sectional configuration diagram illustrating the substrate processing apparatus 1 according to the first and second preferred embodiments of the present invention during wafer conveyance.

(Processing Chamber)

As shown in FIGS. 2 and 3, the substrate processing apparatus 1 is provided with a processing container 202. The processing container 202 is configured as a flat sealed container in which a transverse cross-sectional surface has a circular shape. In addition, the processing container 202 is formed from a metallic material, for example, aluminum (Al) or stainless steel (SUS). A processing chamber 201, which processes a wafer 200 such as a silicon wafer as a substrate, is formed in the processing container 202.

(Support Base)

A support base 203 that supports the wafer 200 is provided inside the processing chamber 201. A susceptor 217, which is formed from, for example, quartz (SiO₂), carbon ceramic, silicon carbide (SiC), aluminum oxide (Al₂O₃), or aluminum nitride (AlN), is provided as a support plate on a top surface of the support base 203 with which the wafer 200 comes into direct contact. In addition, a heater 206 as heating means (heating source) for heating the wafer 200 is embedded in the support base 203. In addition, a lower end portion of the support base 203 penetrates through a lower portion of the processing container 202.

(Elevation Mechanism)

An elevation mechanism 207b that moves the support base 203 vertically, is provided at the outside of the processing chamber 201. When this elevation mechanism 207b operates to vertically move the support base 203, the wafer 200 that is supported on the susceptor 217 may be vertically moved. The support base 203 is lowered down to a position (a wafer conveyance position) as shown in FIG. 3 during conveyance of the wafer 200, and is lifted up to a position (a wafer processing position) as shown in FIG. 2 during processing of the wafer 200. In addition, the periphery of the lower end portion of the support base 203 is covered with a bellows 203a, and the inside of the processing chamber 201 is maintained in an airtight state.

(Lift Pin)

In addition, for example, three lift pins 208b are provided in the bottom surface (floor surface) of the processing chamber 201 to vertically stand up. In addition, penetration holes 208a through which the lift pins 208b penetrate are provided in the support base 203 (also including the susceptor 217) at positions corresponding to the lift pins 208b, respectively. In addition, when the support base 203 is lowered down to the wafer conveyance position, as shown in FIG. 3, an upper end portion of each of the lift pins 208b protrudes from a top surface of the susceptor 217 and the lift pins 208b support the wafer 200 from the lower side thereof. In addition, when the support base 203 is lifted up to the wafer processing position, as shown in FIG. 2, the lift pins 208b sink from the top surface of the susceptor 217, and thus the susceptor 217 supports the wafer 200 from the lower side thereof. In addition, the lift pins 208b come into direct contact with the wafer 200, and thus it is preferable that the lift pins 208b are formed from a material, for example, quartz or alumina.

(Wafer Conveyance Port)

A wafer conveyance port 250, through which the wafer 200 is conveyed to the inside or outside of the processing chamber 201, is provided in an inner wall side surface of the processing chamber 201 (processing container 202). A gate valve 251 is provided in the wafer conveyance port 250. When the gate valve 251 is opened, the inside of the processing chamber 201 and the inside of a conveyance chamber (preliminary chamber) 271 communicate with each other. The conveyance chamber 271 is formed inside a conveyance container (sealed container) 272, and a conveyance robot 273 that conveys the wafer 200 is provided inside the conveyance chamber 271. The conveyance robot 273 is provided with a conveyance arm 273a that supports the wafer 200 during conveyance of the wafer 200. When the gate valve 251 is opened in a state in which the support base 203 is lowered down to the wafer conveyance position, the wafer 200 may be conveyed between the inside of the processing chamber 201 and the inside of the conveyance chamber 271 by the conveyance robot 273. The wafer 200 that is conveyed to the inside of the processing chamber 201 is temporarily mounted on the lift pins 208b as described above. In addition, a load lock chamber (not shown) is provided on a side of the conveyance chamber 271, which is opposite to a side at which the wafer conveyance port 250 is provided, and thus the wafer 200 may be conveyed between the inside of the load lock chamber and the inside of the conveyance chamber 271 by the conveyance robot 273. In addition, the load lock chamber functions as a preliminary chamber that temporarily accommodates wafer 200 that is processed or not processed.

(Exhaust System)

An exhaust port 260 that exhausts an atmosphere inside the processing chamber 201 is provided in the inner wall side surface of the processing chamber 201 (processing container 202) on a side that is opposite to the wafer conveyance port 250. An exhaust pipe 261 is connected to the exhaust port 260 through the exhaust chamber 260a, and a pressure adjustor 262 such as an APC (Auto Pressure Controller) that controls the inside of the processing chamber 201 to a predetermined pressure, a raw material recovery trap 263, and a vacuum pump 264 are serially connected to the exhaust pipe 261 in that order. Mainly, the exhaust port 260, the exhaust chamber 260a, the exhaust pipe 261, the pressure adjustor 262, the raw material recovery trap 263, and the vacuum pump 264 make up the exhaust system (exhaust line).

(Gas Introduction Port)

A gas introduction port 210, through which various kinds of gases are introduced to the inside of the processing chamber 201, is provided on a top surface (ceiling wall) of a shower head 240 to be described later, which is provided at an upper portion of the processing chamber 201. In addition, a configuration of a gas supply system that is connected to the gas introduction port 210 will be described later.

(Shower Head)

The shower head 240 as a gas dispersing mechanism is provided between the gas introduction port 210 and the processing chamber 201. The shower head 240 is provided with a dispersion plate 240a that disperses a gas introduced through the gas introduction port 210, and a shower plate 240b that more uniformly disperses the gas that passes through the dispersion plate 240a, and supplies the uniformly dispersed gas to a surface of the wafer 200 on the support base 203. The dispersion plate 240a and the shower plate 240b are provided with plural ventilation holes. The dispersion plate 240a is disposed to be opposite to the top surface of the shower head 240 and the shower plate 240b, and the shower plate 240b is disposed to be opposite to the wafer 200 on the support base 203. In addition, spaces are formed between the top surface of the shower head 240 and the dispersion plate 240a and between the dispersion plate 240a and the shower plate 240b, respectively, and these spaces function as a first buffer space (dispersion chamber) 240c that disperses the gas supplied through the gas introduction port 210, and a second buffer space 240d that diffuses the gas that passes through the dispersion plate 240a, respectively.

(Exhaust Duct)

A step portion 201a is provided on the inner wall side surface of the processing chamber 201 (processing container 202). This step portion 201a is configured to maintain a conductance plate 204 at the vicinity of the wafer processing position. The conductance plate 204 is configured as one sheet of donut-shaped (ring state) circular plate having a hole accommodating the wafer 200 at an inner peripheral portion thereof. Plural discharge ports 204a, which are arranged with a predetermined interval in a circumferential direction, are provided at an outer peripheral portion of the conductance plate 204. The discharge port 204a is discontinuously formed in order for the outer peripheral portion of the conductance plate 204 to support the inner peripheral portion of the conductance plate 204.

On the other hand, a lower plate 205 is hooked on the outer peripheral portion of the support base 203. The lower plate 205 is provided with a ring-shaped concave portion 205b and a flange portion 205a that is formed integrally with an inner-side upper portion of the concave portion 205b. The concave portion 205b is provided to block a gap between the outer peripheral portion of the support base 203 and the inner wall side surface of the processing chamber 201. A plate exhaust port 205c that discharges (circulates) gas from the inside of the concave portion 205b to the exhaust port 260 side is provided at a part of a lower portion of the concave portion 205b in the vicinity of the exhaust port 260. The flange portion 205a functions as a hook portion that is hooked on an upper peripheral edge of the support base 203. Since the flange portion 205a is hooked on the upper peripheral edge of the support base 203, along with vertical movement of the support base 203, the lower plate 205 moves vertically together with the support base 203.

When the support base 203 is lifted up to the wafer processing position, the lower plate 205 is also lifted up to the wafer processing position. As a result, the conductance plate 204, which is maintained in the vicinity of the wafer processing position, closes a top surface portion of a concave portion 205b of the lower plate 205, and thus an exhaust duct 259 in which the inside of the concave portion 205b is set as a gas flow region is formed. In addition, at this time, due to the exhaust duct 259 (the conductance plates 204 and the lower plate 205) and the support base 203, the inside of the processing chamber 201 is divided into a processing chamber upper portion that is located at an upper side in relation to the exhaust duct 259 and a processing chamber lower portion that is located at a lower side in relation to the exhaust duct 259. In addition, it is preferable that the conductance plate 204 and the lower plate 205 be formed from a material that may be maintained at a high temperature, for example, quartz for high-temperature resistance and high-load resistance, in consideration of a case in which a reaction product that is deposited on an inner wall of the exhaust duct 259 is etched (a case of being self-cleaned).

Here, a gas flow inside the processing chamber 201 during wafer processing will be described. First, the gas supplied to the upper portion of the shower head 240 through the gas introduction port 210 is introduced into the second buffer space 240d from the plural holes of the dispersion plate 240a via the first buffer space (dispersion chamber) 240c, and is supplied to the inside of the processing chamber 201 through the plural holes of the shower plate 240b, and is uniformly supplied onto the wafer 200. In addition, the gas supplied onto the wafer 200 flows radially toward an outer side in a radial direction of the wafer 200. In addition, a surplus of the gas after being brought into contact with the wafer 200 flows radially on the exhaust duct 259 that is positioned at the outer peripheral portion of the wafer 200, that is, on the conductance plate 204 toward an outer side in a radial direction of the wafer 200, and is discharged to the inside of the gas flow region (the inside of the concave portion 205b) in the exhaust duct 259 from the discharge port 204a provided in the conductance plate 204. Then the gas flows through the inside of the exhaust duct 259 and is exhausted to the exhaust port 260 through the plate exhaust port 205c. When the gas is made flow in this manner, inflow of the gas to a lower portion of the processing chamber 201, that is, the rear surface of the support base 203 or the lower surface side of the processing chamber 201 is suppressed.

(Gas Supply System)

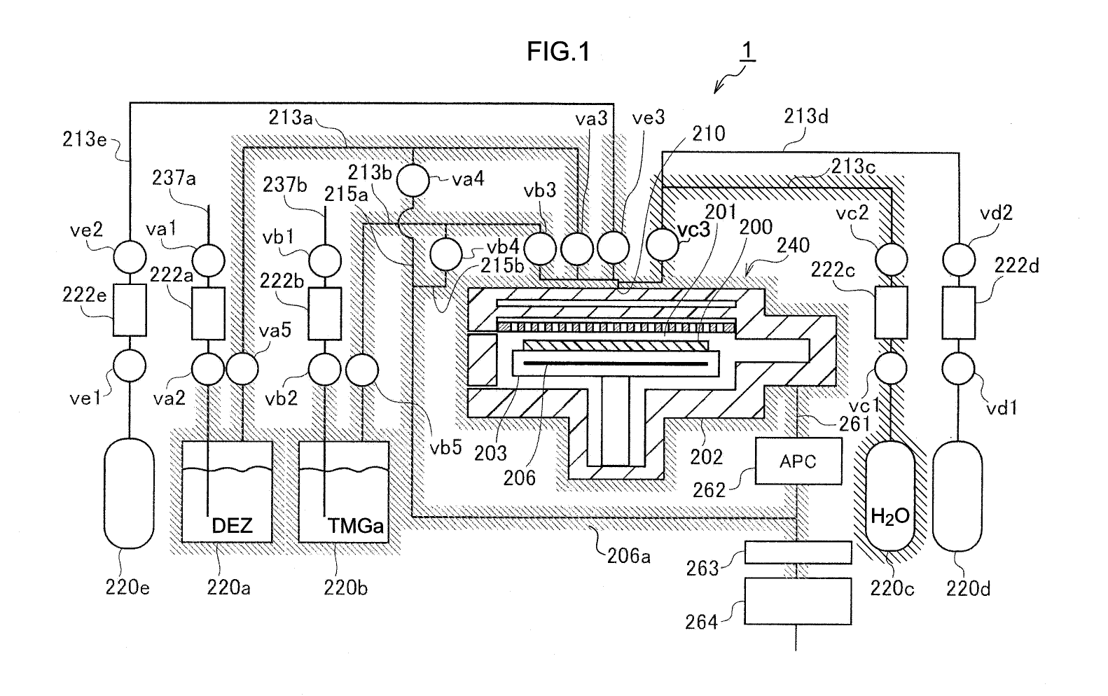

Subsequently, a configuration of a gas supply system that is connected to the above-described gas introduction port 210 will be described with reference to FIG. 1. FIG. 1 shows a configuration diagram illustrating the gas supply system (the gas supply line) that is provided in a substrate processing apparatus 1 according to first and second preferred embodiments of the invention.

The gas supply system, which is provided in the substrate processing apparatus 1, includes a bubbler as a vaporization portion that vaporizes a liquid raw material that is in a liquid state at normal temperature, a raw gas supply system that supplies the raw material gas obtained by vaporizing the liquid raw material in the bubbler to the inside of the processing chamber 201, and a reaction gas supply system that supplies a reaction gas that is different from the raw material gas to the inside of the processing chamber 201. Furthermore, the substrate processing apparatus 1 includes a purge gas supply system that supplies a purge gas to the inside of the processing chamber 201, and a vent (bypass) system that exhausts the raw material gas supplied from the bubbler without supplying the raw material gas to the inside of the processing chamber 201 in order for the raw material gas bypass the processing chamber 201. Hereinafter, configurations of respective portions will be described.

(Bubbler)

A first raw material container (bubbler) 220a that accommodates a first raw material (raw material A) as a liquid raw material, and a second raw material container (bubbler) 220b that supplies a second raw material (raw material B) as a liquid raw material are provided to the outside of the processing chamber 201. The bubbler 220a and the bubbler 220b are configured as a tank (sealed container) that is capable of accommodating (charging) the liquid raw material in the inside thereof, respectively. In addition, the bubbler 220a and the bubbler 220b are also configured as a vaporization portion that vaporizes the first raw material and the second raw material by bubbling and generates a first raw material gas and a second raw material gas. In addition, a sub-heater 206a that heats the bubbler 220a, the bubbler 220b, and a liquid raw material inside thereof is provided at the periphery of the bubbler 220a and the bubbler 220b. As the first raw material, for example, Diethyl zinc (Zn(CH₂CH₃)₂, DEZ) that is a metallic liquid raw material containing Zn (zinc) elements is used, and as the second raw material, for example, Trimethyl gallium ((CH₃)₃Ga, TMGa) that is a metallic liquid raw material containing Ga (gallium) elements is used.

A carrier gas supply pipe 237a and a carrier gas supply pipe 237b are connected to the bubbler 220a and the bubbler 220b, respectively. A carrier gas supply source (not shown) is connected to each upstream side end of the carrier gas supply pipe 237a and the carrier gas supply pipe 237b. In addition, each downstream side end of the carrier gas supply pipe 237a and the carrier gas supply pipe 237b is immersed in the liquid raw material that is accommodated in each of the bubbler 220a and the bubbler 220b. A mass flow controller (MFC) 222a as a flow rate controller that controls a supply flow rate of a carrier gas, and valves va1 and va2 that control supply of the carrier gas are provided to the carrier gas supply pipe 237a. A mass flow controller (MFC) 222b as a flow rate controller that controls a supply flow rate of the carrier gas, and valves vb1 and vb2 that control supply of the carrier gas are provided to the carrier gas supply pipe 237b. In addition, as the carrier gas, it is preferable to use a gas that does not react with the liquid raw material, and, for example, an inert gas such as an N₂ gas and an Ar gas is appropriately used. The first carrier gas supply system (the first carrier gas supply line) is mainly configured by the carrier gas supply pipe 237a, the MFC 222a, and the valves va1 and va2. The second carrier gas supply system (the second carrier gas supply line) is mainly configured by the carrier gas supply pipe 237b, the MFC 222b, and the valves vb1 and vb2.

According to the above-described configuration, when the valves va1, va2, vb1, and vb2 are opened and the carrier gas of which flow rate is controlled by the MFCs 222a and 222b is supplied to the inside of the bubbler 220a and the bubbler 220b from the carrier gas supply pipe 237a and the carrier gas supply pipe 237b, the first raw material and the second raw material that are accommodated in the bubbler 220a and the bubbler 220b are vaporized by bubbling to generate the first raw material gas and the second raw material gas. In addition, a supply flow rate of each of the first raw material gas and the second raw material gas may be calculated from the supply flow rate of the carrier gas. That is, the supply flow rate of each of the first raw material gas and the second raw material gas may be controlled by controlling the supply flow rate of the carrier gas.

(Raw Material Gas Supply System)

A first raw material gas supply pipe 213a and a second raw material gas supply pipe 213b, which supply the first raw material gas and the second raw material gas that are generated in the bubbler 220a and the bubbler 220b to the inside of the processing chamber 201, are connected to the bubbler 220a and the bubbler 220b, respectively. Upstream side ends of the first raw material gas supply pipe 213a and the second raw material gas supply pipe 213b are communicated with spaces that are present in the upper portions of the bubbler 220a and the bubbler 220b, respectively. Downstream side ends of the first raw material gas supply pipe 213a and the second raw material gas supply pipe 213b meet and are connected to the gas introduction port 210.

In addition, valves va5 and va3 are provided in the first raw material gas supply pipe 213a in that order from an upstream side. The valve va5 is a valve that controls the supply of the first raw material gas to the inside of the first raw material gas supply pipe 213a from the bubbler 220a and is provided in the vicinity of the bubbler 220a. The valve va3 is a valve that controls the supply of the first raw material gas to the inside of the processing chamber 201 from the first raw material gas supply pipe 213a and is provided in the vicinity of the gas introduction port 210. In addition, valves vb5 and vb3 are provided in the second raw material gas supply pipe 213b in that order from an upstream side. The valve vb5 is a valve that controls the supply of the second raw material gas to the inside of the second raw material gas supply pipe 213b from the bubbler 220b and is provided in the vicinity of the bubbler 220b. The valve vb3 is a valve that controls the supply of the second raw material gas to the inside of the processing chamber 201 from the second raw material gas supply pipe 213b and is provided in the vicinity of the gas introduction port 210. The valves va3, the valve vb3, and valve ve3 to be described later are configured as a highly durable high-speed gas valve. The highly durable high-speed gas valve is an integrated valve that is configured so as to perform quick conversion of gas supply and exhaust of gas within a short time. In addition, the valve ve3 is a valve that controls introduction of a purge gas that purges a space between the valve va3 of the first raw material gas supply pipe 213a and the gas introduction port 210, and a space between the valve vb3 of the second raw material gas supply pipe 213b and the gas introduction port 210 at a high speed, and then purges the inside of the processing chamber 201.

Due to the above-described configuration, it is possible to generate the first raw material gas and the second raw material gas by vaporizing the liquid raw material in the bubbler 220a and the bubbler 220b and to supply the first raw material gas and the second raw material gas to the inside of the processing chamber 201 from the first raw material gas supply pipe 213a and the second raw material gas supply pipe 213b by opening the valves va5, va3, vb5, and vb3. The first raw material gas supply system (the first raw material gas supply line) is mainly configured by the first raw material gas supply pipe 213a, and the valves va5 and va3, and the second raw material gas supply system (the second raw material gas supply line) is mainly configured by the second raw material gas supply pipe 213b, and the valves vb5 and vb3.

In addition, the first raw material supply system (the first raw material supply line) is mainly configured by the first carrier gas supply system, the bubbler 220a, and the first raw material gas supply system, and the second raw material supply system (the second raw material supply line) is mainly configured by the second carrier gas supply system, the bubbler 220b, and the second raw material gas supply system. Therefore, the first raw material supply system and the reaction gas supply system to be described later make up a first processing gas supply system, and the second raw material gas supply system makes up a second processing gas supply system.

(Reaction Gas Supply System)

In addition, a reaction gas supply source 220c that supplies a reaction gas is provided at the outside of the processing chamber 201. An upstream side end of a reaction gas supply pipe 213c is connected to the reaction gas supply source 220c. A downstream side end of the reaction gas supply pipe 213c is connected to the gas introduction port 210 via a valves vc3. A mass flow controller (MFC) 222c as a flow rate controller that controls a supply flow rate of the reaction gas, and valves vc1 and vc2 that control supply of the reaction gas are provided to the reaction gas supply pipe 213c. As the reaction gas, for example, water vapor (H₂O) is used. A reaction gas supply system (a reaction gas supply line) is mainly configured by the reaction gas supply pipe 213c, the MFC 222c, and the valves vc1, vc2, and vc3.

(Purge Gas Supply System)

In addition, purge gas supply sources 220d and 220e that supply a purge gas are provided at the outside of the processing chamber 201. Upstream side ends of purge gas supply pipes 213d and 213e are connected to the purge gas supply sources 220d and 220e, respectively. A downstream side end of the purge gas supply pipe 213d meets the reaction gas supply pipe 213c and is connected to the gas introduction port 210 via the valve vc3. A downstream side end of the purge gas supply pipe 213e meets the first raw material gas supply pipe 213a and the second raw material gas supply pipe 213b and is connected to the gas introduction port 210 via the valve ve3. Mass flow controllers (MFCs) 222d and 222e as a flow rate controller that controls a supply flow rate of the purge gas, and valves vd1, vd2, ve1, and ve2 that control supply of the purge gas are provided to the purge gas supply pipes 213d and 213e, respectively. As the purge gas, for example, an inert gas such as N₂ gas and Ar gas is used. A purge gas supply system (a purge gas supply line) is mainly configured by the purge gas supply pipes 213d and 213e, the MFCs 222d and 222e, and the valves vd1, vd2, vc3, ve1, ve2, and ve3.

(Vent (Bypass) System)

In addition, upstream side ends of a first vent pipe 215a and a second vent pipe 215b are connected to the first raw material gas supply pipe 213a and the second raw material gas supply pipe 213b on upstream sides thereof in relation to the valves va3 and vb3, respectively. In addition, downstream side ends of the first vent pipe 215a and the second vent pipe 215b meet and are connected to the exhaust pipe 261 on a downstream side thereof in relation to the pressure adjustor 262 and on an upstream side thereof in relation to the raw material recovery trap 263. Valves va4 and vb4 that control gas flow are provided to the first vent pipe 215a and the second vent pipe 215b, respectively.

According to the above-described configuration, when the valves va3 and vb3 are closed and the valves va4 and vb4 are opened, the gas flowing inside the first raw material gas supply pipe 213a and the second raw material gas supply pipe 213b may be made to bypass the processing chamber 201 via the first vent pipe 215a and the second vent pipe 215b, respectively, and may be exhausted to the outside of the processing chamber 201 from the exhaust pipe 261 without being supplied to the processing chamber 201. A first vent system (a first vent line) is mainly configured by the first vent pipe 215a and the valve va4, and a second vent system (a second vent line) is mainly configured by the second vent pipe 215b and the valve vb4.

In addition, as described above, the sub-heater 206a is provided at the periphery of the bubbler 220a and the bubbler 220b. In addition to this, the sub-heater 206a is also provided at the periphery of the carrier gas supply pipe 237a, the carrier gas supply pipe 237b, the first raw material gas supply pipe 213a, the second raw material gas supply pipe 213b, the first vent pipe 215a, the second vent pipe 215b, the exhaust pipe 261, the processing container 202, the shower head 240, and the like. The sub-heater 206a is configured to heat these members, for example, to a temperature of 100° C. or less so as to prevent re-liquefaction of the first raw material gas and the second raw material gas at the inside of these members, respectively.

In addition, the sub-heater 206a is also provided at the periphery of the reaction gas supply source 220c, the reaction gas supply pipe 213c, the MFC 222c, and the valves vc1, vc2, and vc3 and is configured to prevent the re-liquefaction of the reaction gas.

(Controller)

In addition, the substrate processing apparatus 1 is provided with a controller 280 that controls an operation of each portion of the substrate processing apparatus 1. The controller 280 controls the operation of the gate valve 251, the elevation mechanism 207b, the conveyance robot 273, the heater 206, the sub-heater 206a, the pressure adjustor (APC) 262, the vacuum pump 264, the valves va1 to va5, vb1 to vb5, vc1 to vc3, vd1 and vd2, ve1 to ve3, the flow rate controllers 222a, 222b, 222c, 222d, and 222e, and the like.

### (2) Structure of Semiconductor Device and Substrate Processing Process

Next, description will be made with respect to a structure of a semiconductor device relating to the first and second preferred embodiments of the invention, and a substrate processing process of forming a thin film on a wafer by using the above-described substrate processing apparatus as one process of the semiconductor device manufacturing processes. In addition, in the following description, the operation of the respective portions making up the substrate processing apparatus is controlled by the controller 280.

As a gate electrode of a MOSFET, a capacitor electrode of a DRAM, and the like, a metal, which has a low work function when being present a pure metal but exhibits a high conductive property with high work function when being oxidized, is used. In a case where the metal is used as a lower electrode of a capacitor of the DRAM, even in an oxidizing atmosphere when forming an insulating film on the lower electrode, the electrode may be present without deteriorating film qualities such as a conductive property and a work function. In addition, in a case of using Co and Ni, or in a case of inserting a TiN thin film between the Co or Ni and the insulating film, due to oxidization thereof, a phenomenon in which a total electrostatic capacitance of the capacitor decreases is recognized. However, the conductive oxide film is already oxidized, and thus even when the conductive oxide film is left in an oxidizing atmosphere, the film qualities do not vary and the conductive oxide film exhibits a conductive property as an oxide film. Therefore, the total capacity as capacitance does not decrease. In addition, even in a case in which the metal is used an upper electrode of the capacitor of the DRAM or the gate electrode of the MOSFET, even when the upper electrode or the gate electrode comes into contact with an underlying insulating film containing oxygen, a film may be formed without deteriorating the film qualities such as the conductive property and the work function, and without decreasing the total capacity as capacitance.

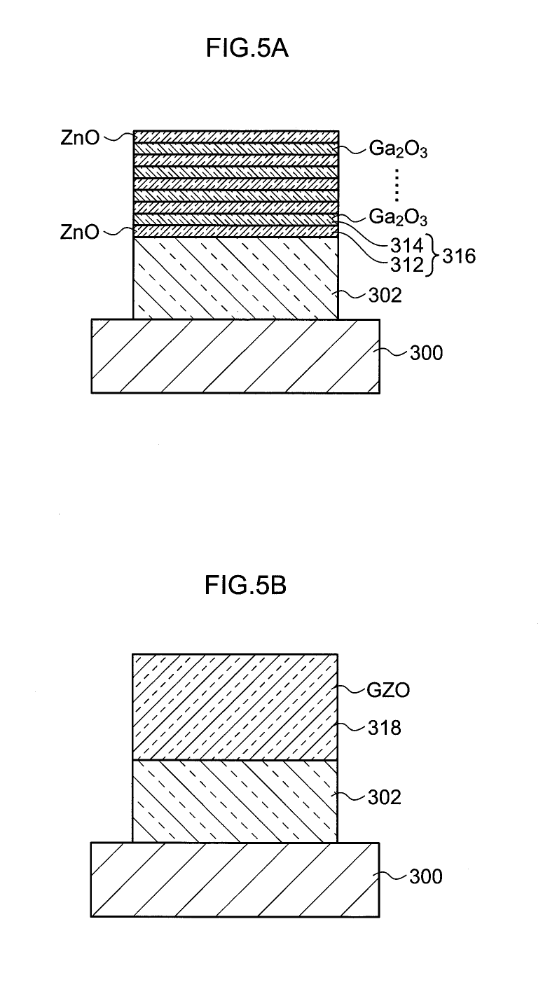

Hereinafter, description will be made with respect to a case in which a conductive oxide film is used for the gate electrode of the MOSFET as the first preferred embodiment of the invention. As shown in FIG. 5A, a high dielectric constant (High-k) gate insulating film 302 formed from HfSiOx is formed on a silicon substrate 300, and a film 316 having a laminated structure in which plural ZnO films 312 and plural Ga₂O₃ films 314 that have a film thickness of 10 nm are alternately laminated is formed on the gate insulating film 302. The reason why the ZnO film 312 is firstly formed to be present at an immediately upper side of the gate insulating film 302 is because the ZnO film 312 is a conductive oxide film and Ga₂O₃ is an additive for work function modulation (change). In addition, the reason why the laminated structure in which the plural ZnO films 312 and the plural Ga₂O₃ films 314 are alternately laminated is firstly formed is to make Ga₂O₃ as an additive for the work function modulation be uniformly distributed in a plane of the silicon substrate 300.

In addition, after the laminated structure undergoes thermal hysteresis in a subsequent MOSFET manufacturing process, as shown in FIG. 5B, ZnO and Ga₂O₃ are mixed with each other, and thus a GZO (Ga-doped ZnO) film 318 containing Ga₂O₃ as an additive in ZnO is formed. The ZnO film exhibits a conductive property as an oxide film. Therefore, in a case where the GZO film 318 is used as a gate electrode of the MOSFET, even when the GZO film 318 comes into contact with the underlying gate insulating film 302 containing oxygen, the film qualities such as the conductive property and the work function do not deteriorate. In addition, since Ga₂O₃ is contained, even when a high dielectric constant (High-k) insulating film that is formed from HfSiOx or the like is used for the gate insulating film 302, the GZO film 318 has a sufficient work function as the gate electrode of the MOSFET. For example, the work function of the ZnO film is 3.3 eV, and the work function of the GaO film is approximately 6 eV. The work function may be changed by changing a compositional ratio of the ZnO film and the GaO film that are contained in the GZO film. For example, in a GZO film in which 5 at. % of Ga is added in the ZnO film, the work function varies from 3.62 eV to 4.37 eV. In addition, in a GZO film in which 15% of GaO film is added to the ZnO film, the work function varies to 5.66 eV.

In addition, instead of the ZnO film, an indium oxide film may be used. In addition, a film, which contains at least one of oxides of aluminum, tin, gallium, and the like as an additive in a Zn oxide film or an indium oxide film, may be used as a gate electrode.

In addition, in a case of using an oxide film of Mo, W, or V as the gate electrode, the oxide film of Mo, W, or V exhibits a conductive property as an oxide film. Therefore, in a case of using this oxide film as the gate electrode of the MOSFET, even when the oxide film comes into contact with the underlying gate insulating film 302 containing oxygen, the film qualities such as the conductive property and the work function do not deteriorate. In addition, even when a high dielectric constant (High-k) insulating film that is formed from HfSiOx or the like is used for the gate insulating film 302, since the oxide film of Mo, W, or V has a sufficient work function as the gate electrode of the MOSFET, it is not necessary to form Ga₂O₃ film or the like, and the oxide film of Mo, W, or V may be formed in a single layer structure.

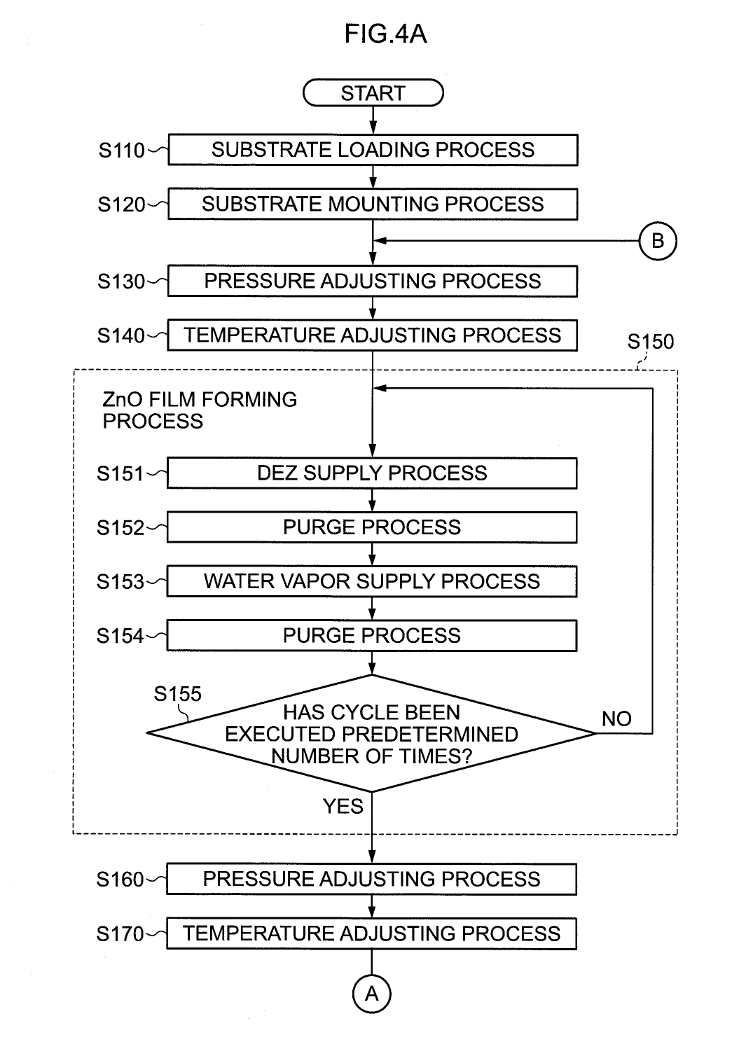

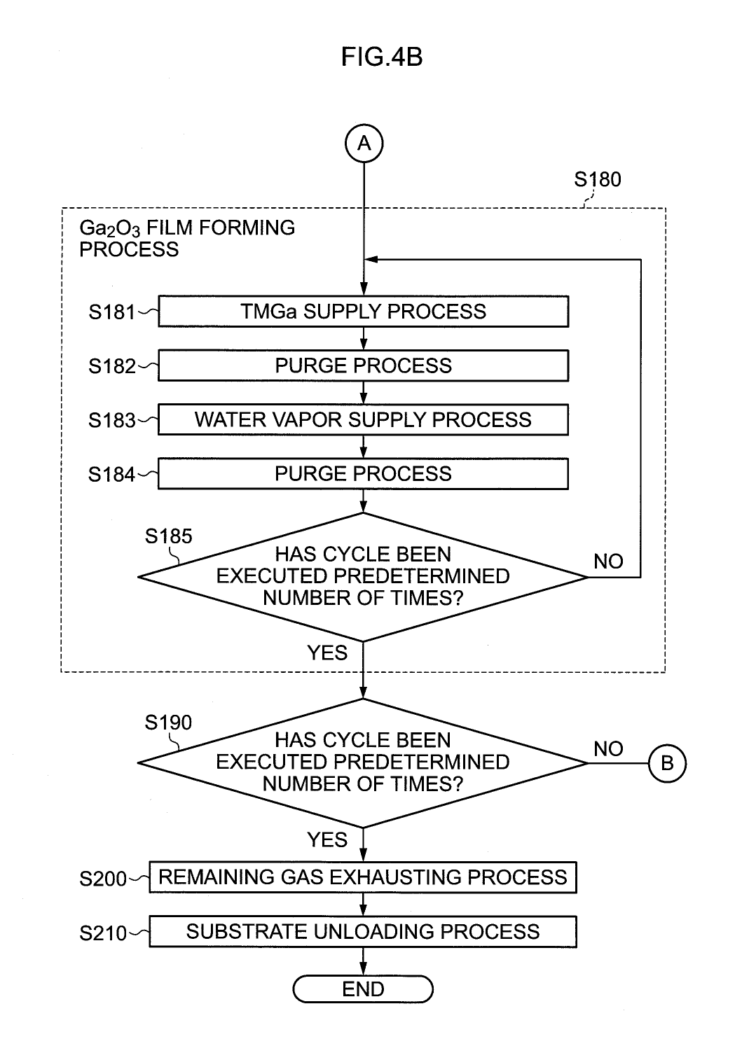

Next, description will be made with respect to a substrate processing process in which the gate electrode of the MOSFET is formed using the above-described substrate processing apparatus 1 with reference to a flow diagram in FIGS. 4A and 4B. In addition, in the following description, the operation of the respective portions making up the substrate processing apparatus is controlled by the controller 280. Here, plural kinds of processing gases are alternately supplied to the wafer 200 without being mixed, and a thin film is formed on the wafer 200. At this time, the film thickness of the thin film that is formed may be controlled by controlling the number of supply times of the processing gases.

Hereinafter, description will be made with respect to a process of forming the film 316, which has a laminated structure in which the plural ZnO films 312 and the plural Ga₂O₃ films 314 are alternately laminated, on an HfSiOx film as the gate insulating film 302 that is formed in advance on the wafer 200 as the substrate 300. In addition, each of the ZnO films 312 is formed by alternately supplying a first raw material gas obtained by vaporizing a first raw material (Diethyl Zinc (Zn(CH₂CH₃)₂, DEZ)) and a reaction gas (water vapor (H₂O)) to the inside of the processing chamber 201 that accommodates the wafer 200. In addition, each of the Ga₂O₃ film 314 is formed by alternately supplying a second raw material gas obtained by vaporizing a second raw material (Trimethyl gallium ((CH₃)₃Ga, TMGa)) and the reaction gas (water vapor (H₂O)) to the inside of the processing chamber 201 that accommodates the wafer 200.

Substrate Loading Process (S1) and Substrate Mounting Process (S2)

First, the elevation mechanism 207b is made to operate so as to lower the support base 203 to a wafer conveyance position shown in FIG. 3. In addition, the gate valve 251 is opened, and thus the processing chamber 201 and the conveyance chamber 271 communicate with each other. In addition, the wafer 200 that is an object to be processed is loaded from the conveyance chamber 271 to the inside of the processing chamber 201 by the conveyance robot 273 in a state of being supported by a conveyance arm 273a (step S110). In addition, the HfSiOx film as the gate insulating film 302 is formed in advance on the wafer 200 that is an object to be processed. The wafer 200 that is loaded to the inside of the processing chamber 201 is temporarily mounted on the lift pins 208b that protrude from the top surface of the support base 203. When the conveyance arm 273a of the conveyance robot 273 returns to the inside of the conveyance chamber 271 from the inside of the processing chamber 201, the gate valve 251 is closed.

Subsequently, the elevation mechanism 207b is made to operate so as to lift up the support base 203 to the wafer processing position shown in FIG. 2. As a result, the lift pins 208b are buried from the top surface of the support base 203 and the wafer 200 is mounted on the susceptor 217 on the top surface of the support base 203 (step S120).

Pressure Adjusting Process (S3) and Temperature Adjusting Process (S4)

Subsequently, a pressure inside the processing chamber 201 is controlled to be a predetermined processing pressure by the pressure adjustor (APC) 262 (step S130). In addition, a surface temperature of the wafer 200 is controlled to be a predetermined processing temperature by adjusting electric power supplied to the heater 206 (step S140). In addition, the temperature adjusting process (step S140) may be performed concurrently with the pressure adjusting process (step S130), or may be performed antecedently to the pressure adjusting process (step S130). Here, the predetermined processing temperature and the predetermined processing pressure represent a processing temperature and a processing pressure at which the ZnO film may be formed in a ZnO film forming process (step S150) to be described later. Preferably, the predetermined processing temperature and the predetermined processing pressure represent a processing temperature and a processing pressure at which self-decomposition of a first raw material gas that is supplied in a Zn raw material supply process (step S151) does not occur. The predetermined processing temperature is, for example, 50 to 200° C., and appropriately 100° C., and the predetermined processing pressure is, for example, 10 to 1,000 Pa, and appropriately 20 Pa.

In addition, in the substrate loading process (step S110), the substrate mounting process (step S120), the pressure adjusting process (step S130), and the temperature adjusting process (step S140), the valves va3 and vb3 are closed and the valves vd1, vd2, vc3, ve1, ve2, and ve3 are opened while operating the vacuum pump 264 in order for the N₂ gas to constantly flow to the inside of the processing chamber 201. According to this configuration, adhesion of particles onto the wafer 200 may be suppressed.

In combination with the process steps S110 to S140, DEZ that is a Zn raw material as the first raw material is vaporized to generate (preliminary vaporize) the first raw material gas, that is, a DEZ gas. Specifically, the valves va1, va2, and va5 are opened and a carrier gas of which flow rate is controlled by the MFC 222a is supplied from the carrier gas supply pipe 237a to the inside of the bubbler 220a, and thus the first raw material that is accommodated in the bubbler 220a is vaporized by bubbling to generate the first raw material gas (preliminary vaporizing process). In this preliminary vaporizing process, the valve va4 is opened with the valve va3 closed while operating the vacuum pump 264, and thus the DEZ gas bypasses the processing chamber 201 and is exhausted without being supplied to the inside of the processing chamber 201. It is necessary a predetermined time to stably generate the DEZ gas in the bubbler. Therefore, in this embodiment, the DEZ gas is generated in advance, and a flow path of the DEZ gas is changed by switching on and off of the valves va3 and va4. As a result, stable supply of the DEZ gas to the inside of the processing chamber 201 may be quickly initiated or stopped by the valve switching, and thus this is preferable.

ZnO Film Forming Process (Step S150)

Zn Raw Material (DEZ) Supply Process (Step S151)

Subsequently, the valve va4 is closed and the valve va3 is opened while operating the vacuum pump 264 so as to initiate supply of the DEZ gas to the inside of the processing chamber 201. The first raw material gas is dispersed by the shower head 240 and is uniformly supplied onto the wafer 200 inside the processing chamber 201. A surplus of the first raw material gas flows through the inside of the exhaust duct 259 and is exhausted to the exhaust port 260 and the exhaust pipe 261. At this time, the processing temperature and the processing pressure are set to a processing temperature and a processing pressure at which self-decomposition of the DEZ gas does not occur, and thus a Zn-containing layer is formed on an HfSiOx film as the gate insulating film 302 that is formed in advance on the wafer 200.

In addition, it is preferable that the N₂ gas is made to flow constantly to the inside of the processing chamber 201 by maintaining the valves vd1, vd2, and vc3 in an opened state during supply of the DEZ gas to the inside of the processing chamber 201 so as to prevent invasion of the DEZ gas to the inside of the reaction gas supply pipe 213c and so as to promote diffusion of the DEZ gas in the processing chamber 201.

When a predetermined time has passed since the supply of the DEZ gas was initiated by opening the valve va3, the valve va3 is closed and the valve va4 is opened to stop the supply of the DEZ gas to the inside of the processing chamber 201.

Purge Process (Step S152)

After the supply of the DEZ gas is stopped by closing the valve va3, the valves vd1, vd2, vc3, ve1, ve2, and ve3 are opened to supply the N₂ gas to the inside of the processing chamber 201. The N₂ gas is dispersed by the shower head 240 and is uniformly supplied onto the wafer 200 inside the processing chamber 201. Then, the N₂ gas flows through the inside of the exhaust duct 259 and is exhausted to the exhaust port 260 and the exhaust pipe 261. According to this configuration, the first raw material gas that remains in the processing chamber 201 is removed and the inside of the processing chamber 201 is purged by the N₂ gas.

Reaction Gas Supply Process (Step S153)

When the purging of the inside of the processing chamber 201 is completed, the valves vc1, vc2, and vc3 are opened to initiate supply of the reaction gas (water vapor, H₂O) to the inside of the processing chamber 201. The H₂O gas is dispersed by the shower head 240 and is uniformly supplied onto the wafer 200 inside the processing chamber 201. The H₂O gas reacts with the Zn-containing layer that is formed on the HfSiOx film that is formed in advance on the wafer 200 and generates a ZnO film on the HfSiOx film. A surplus of the H₂O gas or reaction byproducts flow through the inside of the exhaust duct 259 and are exhausted to the exhaust port 260 and the exhaust pipe 261. When a predetermined time has passed since the supply of the H₂O gas was initiated by opening the valves vc1, vc2, and vc3, the valves vc1 and vc2 are closed to stop the supply of the H₂O gas to the inside of the processing chamber 201.

In addition, it is preferable that the N₂ gas is made to flow constantly to the inside of the processing chamber 201 by maintaining the valves ve1, ve2, and ve3 in an opened state during supply of the H₂O gas to the inside of the processing chamber 201 so as to prevent invasion of the H₂O gas to the inside of the DEZ gas supply pipe 213a and the second raw material gas supply pipe 213b and so as to promote diffusion of the H₂O gas in the processing chamber 201.

Purge Process (Step S154)

After the supply of the H₂O gas is stopped by closing the valves vc1 and vc2, the valves vd1, vd2, vc3, ve1, ve2, and ve3 are opened to supply the N₂ gas to the inside of the processing chamber 201. The N₂ gas is dispersed by the shower head 240 and is uniformly supplied onto the wafer 200 inside the processing chamber 201. Then, the N₂ gas that is supplied flows through the inside of the exhaust duct 259 and is exhausted to the exhaust port 260 and the exhaust pipe 261. According to this configuration, the H₂O gas and reaction byproducts that remain in the processing chamber 201 are removed, and the inside of the processing chamber 201 is purged by the N₂ gas.

Predetermined Number of Times Executing Process (Step S155)

The Zn raw material (DEZ) supply process (step S151), the purge process (step S152), the reaction gas supply process (step S153), and the purge process (step S154) are set as one cycle, and this cycle is executed in a predetermined number of times (n1 cycles) to form the ZnO film 312 having a desired film thickness on the HfSiOx film that is formed in advance on the wafer 200.

Pressure Adjusting Process (Step S160) and Temperature Adjusting Process (Step S170)

Subsequently, a pressure inside the processing chamber 201 is controlled to be a predetermined processing pressure by the pressure adjustor (APC) 262 (step S160). In addition, a surface temperature of the wafer 200 is controlled to be a predetermined processing temperature by adjusting electric power supplied to the heater 206 (step S170). In addition, the temperature adjusting process (step S170) may be performed concurrently with the pressure adjusting process (step S160), or may be performed antecedently to the pressure adjusting process (step S160). Here, the predetermined processing temperature and the predetermined processing pressure represent a processing temperature and a processing pressure at which the Ga₂O₃ film may be formed in a Ga₂O₃ film forming process (step S180) to be described later. Preferably, the predetermined processing temperature and the predetermined processing pressure represent a processing temperature and a processing pressure at which self-decomposition of a second raw material gas that is supplied in a Ga raw material supply process (step S181) does not occur. The predetermined processing temperature is, for example, 50 to 200° C., and appropriately 100° C., and the predetermined processing pressure is, for example, 10 to 1,000 Pa, and appropriately 20 Pa.

In addition, in combination with the pressure adjusting process (step S160) to the temperature adjusting process (step S170), the second raw material (TMGa) is vaporized to generate (preliminary vaporize) the second raw material gas (Ga raw material), that is, a TMGa gas for a subsequent Ga₂O₃ film forming process (step S180). Specifically, the valves vb1, vb2, and vb5 are opened and a carrier gas of which flow rate is controlled by the MFC 222b is supplied from the carrier gas supply pipe 237b to the inside of the bubbler 220b, and thus the second raw material that is accommodated in the bubbler 220b is vaporized by bubbling to generate the second raw material gas (preliminary vaporizing process). In this preliminary vaporizing process, the valve vb4 is opened with the valve vb3 closed while operating the vacuum pump 264, and thus the second raw material gas bypasses the processing chamber 201 and is exhausted without being supplied to the inside of the processing chamber 201. It is necessary a predetermined time to stably generate the second raw material gas in the bubbler. Therefore, in this embodiment, the second raw material gas is generated in advance, and a flow path of the second raw material gas is changed by switching on and off of the valves vb3 and vb4. As a result, stable supply of the second raw material gas to the inside of the processing chamber 201 may be quickly initiated or stopped by the valve switching, and thus this is preferable.

Ga₂O₃ Film Forming Process (Step S180)

Ga Raw Material (TMGa) Supply Process (Step S181)

Subsequently, the valve vb4 is closed and the valve vb3 is opened while operating the vacuum pump 264 so as to initiate supply of the second raw material gas (Ga raw material, TMGa) to the inside of the processing chamber 201. The TMGa gas is dispersed by the shower head 240 and is uniformly supplied onto the wafer 200 inside the processing chamber 201. A surplus of the TMGa gas flows through the inside of the exhaust duct 259 and is exhausted to the exhaust port 260 and the exhaust pipe 261. At this time, the processing temperature and the processing pressure are set to a processing temperature and a processing pressure at which self-decomposition of the TMGa gas does not occur, and thus the Ga-containing layer is formed on the ZnO film 312 that is formed as described above on an HfSiOx film as the gate insulating film 302 that is formed in advance on the wafer 200.

In addition, it is preferable that the N₂ gas is made to flow constantly to the inside of the processing chamber 201 by maintaining the valves vd1, vd2, and vc3 in an opened state during supply of the TMGa gas to the inside of the processing chamber 201 so as to prevent invasion of the TMGa gas to the inside of the reaction gas supply pipe 213c and so as to promote diffusion of the TMGa gas in the processing chamber 201.

When a predetermined time has passed since the supply of the TMGa gas was initiated by opening the valve vb3, the valve vb3 is closed and the valve vb4 is opened to stop the supply of the TMGa gas to the inside of the processing chamber 201.

Purge Process (Step S182)

After the supply of the TMGa gas is stopped by closing the valve vb3, the valves vd1, vd2, vc3, ve1, ve2, and ve3 are opened to supply the N₂ gas to the inside of the processing chamber 201. The N₂ gas is dispersed by the shower head 240 and is uniformly supplied onto the wafer 200 inside the processing chamber 201. Then, the N₂ gas flows through the inside of the exhaust duct 259 and is exhausted to the exhaust port 260 and the exhaust pipe 261. According to this configuration, the TMGa gas that remains in the processing chamber 201 is removed and the inside of the processing chamber 201 is purged by the N₂ gas.

Reaction Gas Supply Process (Step S183)

When the purging of the inside of the processing chamber 201 is completed, the valves vc1, vc2, and vc3 are opened to initiate supply of the reaction gas (water vapor, H₂O) to the inside of the processing chamber 201. The H₂O gas is dispersed by the shower head 240 and is uniformly supplied onto the wafer 200 inside the processing chamber 201. The H₂O gas reacts with the Ga-containing layer that is formed on the ZnO film 312 formed as described above on the HfSiOx film formed in advance on the wafer 200 and generates a Ga₂O₃ film on the ZnO film. A surplus of the H₂O gas or reaction byproducts flow through the inside of the exhaust duct 259 and are exhausted to the exhaust port 260 and the exhaust pipe 261. When a predetermined time has passed since the supply of the H₂O gas was initiated by opening the valves vc1, vc2, and vc3, the valves vc1 and vc2 are closed to stop the supply of the H₂O gas to the inside of the processing chamber 201.

In addition, it is preferable that the N₂ gas is made to flow constantly to the inside of the processing chamber 201 by maintaining the valves ve1, ve2, and ve3 in an opened state during supply of the H₂O gas to the inside of the processing chamber 201 so as to prevent invasion of the H₂O gas to the inside of the first raw material gas supply pipe 213a and the second raw material gas supply pipe 213b and so as to promote diffusion of the H₂O gas in the processing chamber 201.

Purge Process (Step S184)

After the supply of the H₂O gas is stopped by closing the valves vc1 and vc2, the valves vd1, vd2, vc3, ve1, ve2, and ve3 are opened to supply the N₂ gas to the inside of the processing chamber 201. The N₂ gas is dispersed by the shower head 240 and is uniformly supplied onto the wafer 200 inside the processing chamber 201. Then, the N₂ gas that is supplied flows through the inside of the exhaust duct 259 and is exhausted to the exhaust port 260 and the exhaust pipe 261. According to this configuration, the reaction gas and reaction byproducts that remain in the processing chamber 201 are removed, and the inside of the processing chamber 201 is purged by the N₂ gas.

Predetermined Number of Times Executing Process (Step S185)

The Ga raw material (TMGa) supply process (step S181), the purge process (step S182), the reaction gas supply process (step S183), and the purge process (step S184) are set as one cycle, and this cycle is executed in a predetermined number of times (n2 cycles) to form the Ga₂O₃ film 314 having a desired film thickness on the ZnO film 312 that is formed on the HfSiOx film formed in advance on the wafer 200 as the gate insulating film 302.

Predetermined Number of Times Executing Process (Step S190)

The pressure adjusting process (step S130) to the ZnO film forming process (step S150), and the pressure adjusting process (step S160) to the Ga₂O₃ film forming process (step S180) are set as one cycle, and this cycle is executed in a predetermined number of times (n3 cycles) to form a film 316, which has a laminated structure in which plural ZnO films 312 and plural Ga₂O₃ films 314 are alternately laminated, on the HfSiOx film that is formed in advance on the wafer 200 as the gate insulating film 302.

Remaining Gas Removing Process (Step S200)

After forming the film 316 having the laminated structure in which the plural ZnO films 312 and the plural Ga₂O₃ films 314 are alternately laminated by performing the predetermined number of times executing process (step S190), the inside of the processing chamber 201 is evacuated, and the valves vd1, vd2, vc3, ve1, ve2, and ve3 are opened to supply the N₂ gas to the inside of the processing chamber 201. The N₂ gas is dispersed by the shower head 240 and is supplied to the inside the processing chamber 201. Then, the N₂ gas is exhausted to the exhaust pipe 261. According to this configuration, the gas or the reaction byproducts that remain in the processing chamber 201 are removed and the inside of the processing chamber 201 is purged by the N₂ gas.

Substrate Unloading Process (Step S210)

Then, in the order opposite to the order illustrated in the substrate loading process (step S110) and the substrate mounting process (step S120), after the film 316 having the laminated structure in which the plural ZnO films 312 having a desired film thickness and the plural Ga₂O₃ films 314 are alternately laminated is formed on the wafer 200, the wafer 200 is unloaded from the processing chamber 201 to the inside of the conveyance chamber 271, whereby the substrate processing process according to this embodiment is terminated.

### Second Embodiment

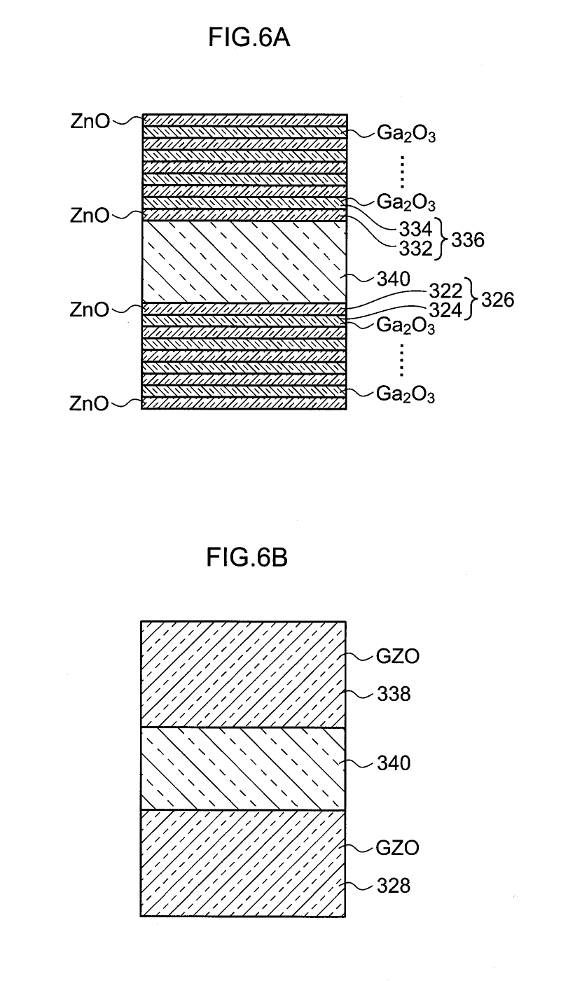

Next, description will be made with respect to a case in which the conductive oxide film is used for the capacitor electrode of the DRAM as a second preferred embodiment of the invention. As shown in FIG. 6A, a film 326 having a laminated structure in which plural ZnO films 322 and plural Ga₂O₃ films 324 are alternately laminated is formed as a lower electrode. A TiO₂ film as a capacitor insulating film 340 is formed on the lower electrode. A film 336 having a laminated structure in which plural ZnO films 332 and plural Ga₂O₃ films 334 are alternately laminated is formed as an upper electrode on the TiO₂ film. The reason why the first one and the final one is ZnO in the overlapping sequence of the plural ZnO films 322 and the plural Ga₂O₃ films 324 and in the overlapping sequence of the plural ZnO films 332 and the plural Ga₂O₃ films 334 is because the ZnO is a conductive oxide film and Ga₂O₃ is an additive for work function modulation. In addition, the reason why the laminated structure in which the plural ZnO films 322 and the plural Ga₂O₃ films 324 are alternately laminated and the laminated structure in which the plural ZnO films 332 and the plural Ga₂O₃ films 334 are alternately laminated are firstly formed is to make Ga₂O₃ as an additive for the work function modulation be uniformly distributed in a plane of the silicon substrate.

In addition, after the laminated structure undergoes thermal hysteresis in a subsequent DRAM manufacturing process, as shown in FIG. 6B, ZnO and Ga₂O₃ are mixed with each other, and thus GZO films 328 and 338 containing Ga₂O₃ as an additive in ZnO are formed. The ZnO film exhibits a conductive property as an oxide film. Therefore, in a case where the GZO films 328 and 338 are used as a capacitor electrode of the DRAM, even when the GZO films 328 and 338 come into contact with the capacitor insulating film 340 containing oxygen, the film qualities such as the conductive property and the work function do not deteriorate. In addition, the ZnO film is already oxidized, and thus even when the ZnO film is left in an oxidizing atmosphere, the film qualities do not vary and the ZnO film exhibits a conductive property as an oxide film. Therefore, the total capacity as capacitance does not decrease. In addition, since Ga₂O₃ is contained, even when a high dielectric constant (High-k) insulating film that is formed from TiO₂ or the like is used for the capacitor insulating film 340, the GZO films 328 and 338 have a sufficient work function as the capacitor electrode of the DRAM. In addition, instead of the ZnO film, an indium oxide film may be used. In addition, a film, which contains at least one of oxides of aluminum, tin, gallium, and the like as an additive in a zinc oxide film or an indium oxide film, may be used as a capacitor electrode.

In addition, in a case of using an oxide film of Mo, W, or V as the capacitor electrode of the DRAM, the oxide film of Mo, W, or V exhibits a conductive property as an oxide film. Therefore, in a case of using this oxide film as the capacitor electrode of the DRAM, even when the oxide film comes into contact with the capacitor insulating film 340 containing oxygen, the film qualities such as the conductive property and the work function do not deteriorate, and the total capacity as capacitance does not decrease. In addition, even when a high dielectric constant (High-k) insulating film that is formed from TiO₂ or the like is used for the capacitor insulating film 340, since the oxide film of Mo, W, or V has a sufficient work function as the capacitor electrode of the DRAM, it is not necessary to form Ga₂O₃ film or the like, and the oxide film of Mo, W, or V may be formed in a single layer structure as described later.

Next, description will be made with respect to a substrate processing process in which the capacitor electrode of the DRAM is formed using the above-described substrate processing apparatus 1.

The film 326, which has a laminated structure in which the plural ZnO films 322 and the plural Ga₂O₃ films 324 are alternately laminated, is formed on an insulating film (not shown) that is formed form SiO₂ or the like and is formed in advance on the wafer 200. In addition, each of the ZnO film 322 is formed by alternately supplying a first raw material gas obtained by vaporizing a first raw material (Diethyl Zinc (Zn(CH₂CH₃)₂, DEZ)) and a reaction gas (water vapor (H₂O) to the inside of the processing chamber 201 that accommodates the wafer 200. In addition, each of the Ga₂O₃ film 324 is formed by alternately supplying a second raw material gas obtained by vaporizing a second raw material (Trimethyl gallium ((CH₃)₃Ga, TMGa)) and the reaction gas (water vapor (H₂O)) to the inside of the processing chamber 201 that accommodates the wafer 200. A forming method is the same as the method of forming the gate electrode of the MOSFET of the above-described first embodiment that is described with reference to FIGS. 4A and 4B, and thus description thereof will not be repeated.

The TiO₂ film as the capacitor insulating film 340 is formed using a film forming device (not shown) different from the above-described substrate processing apparatus 1. Then, the film 336, which has the laminated structure in which the plural ZnO films 332 and the plural Ga₂O₃ films 334 are alternately laminated, is formed on the capacitor insulating film 340 using the substrate processing apparatus 1. A method of forming the film 336 having the laminated structure is the same as the above-described method of forming the film 326 having the laminated structure, in which a film is formed by alternately supplying the plural kinds of raw material, and thus description thereof will not be repeated.

In addition, in the first embodiment, description was made using HfSiOx as the high dielectric constant (High-k) gate insulating film 302, and in this second embodiment, description is made using TiO₂ as the high dielectric constant (High-k) capacitor insulating film 340. However, even in a case of using a high dielectric constant insulating film of HfSiOx, HfO₂, ZrO₂, TiO₂, Nb₂O₅, Ta₂O₅, SrTiO, BaSrTiO, PZT, or the like as the high dielectric constant (High-k) gate insulating film 302 or the high dielectric constant (High-k) capacitor insulating film 340, the above-described gate electrode structure of the MOSFET or the capacitor electrode structure of the DRAM is applicable to this case.

### Third Embodiment

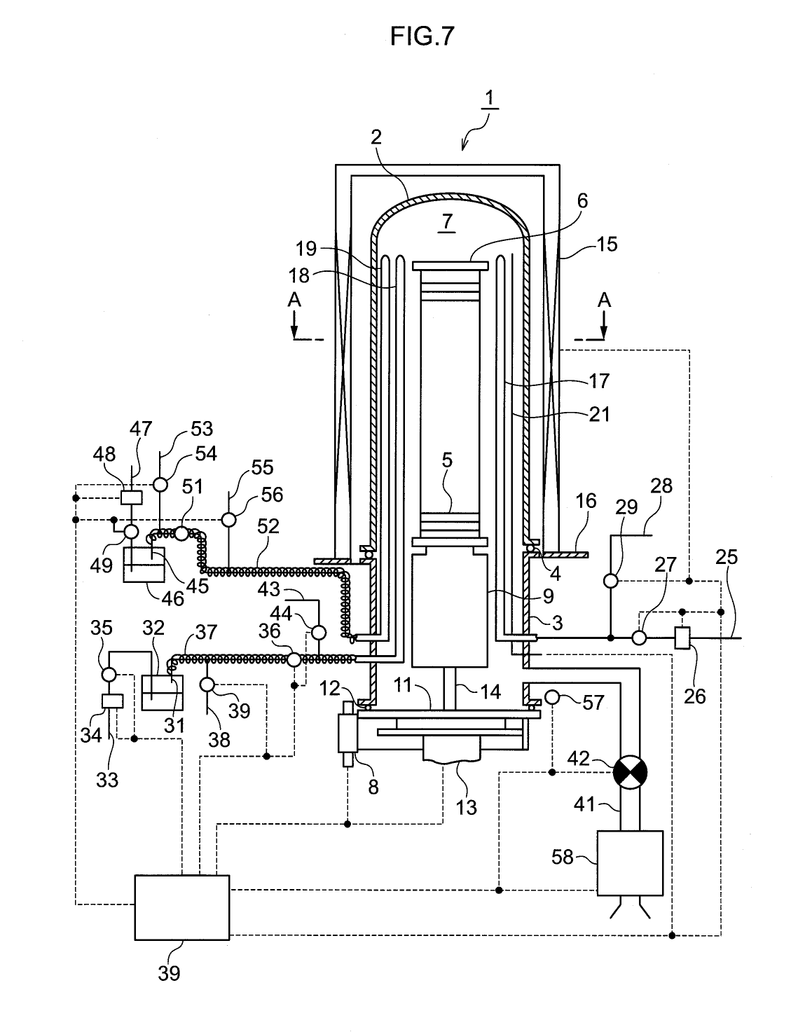

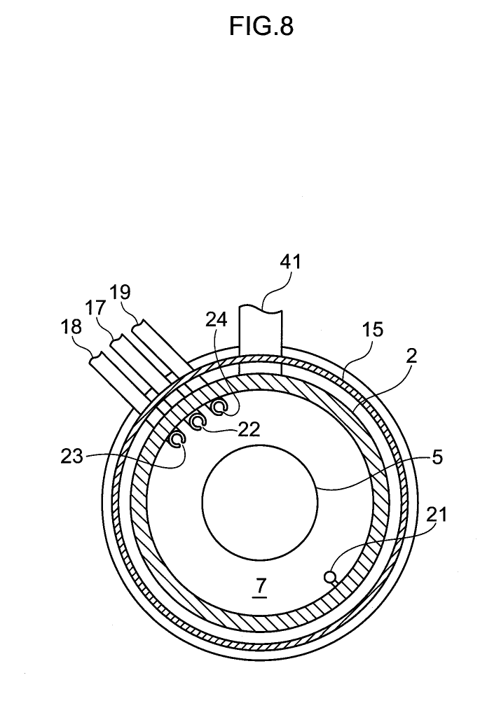

Next, a third preferred embodiment of the invention will be described in detail with reference to the attached drawings. FIG. 7 shows a longitudinal cross-sectional diagram illustrating a processing furnace of the substrate processing apparatus according to the third embodiment of the invention, and FIG. 8 shows a transverse cross-sectional diagram illustrating the processing furnace shown in FIG. 7. This third embodiment is different from the first and second embodiments in that in the first and second embodiments, description was made with respect to an example in which a single wafer type device is used as the substrate processing apparatus that forms the GZO film as the gate electrode, but in the third embodiment, a vertical type device is used as the substrate processing apparatus. A kind of film and a kind of gas that are applicable are the same as the first and second embodiments. Hereinafter, points different from that of the first and second embodiments will be mainly described.

### (1) Configuration Processing Furnace

A processing furnace 1 relating to this embodiment is configured, for example, as a batch-type vertical hot wall processing furnace. As shown in FIG. 7, the processing furnace 1 is provided with a reaction tube 2 and a manifold 3 that supports the reaction tube 2 in the vertical direction. The reaction tube 2 is formed from a non-metallic material that has heat resistance, for example, quartz (SiO₂), silicon carbide (SiC), or the like, and has a cylindrical shape in which an upper end is closed and a lower end is opened.

The manifold 3 is formed from a metallic material, for example, SUS or the like, and has a cylindrical shape in which an upper end and a lower end are opened. A circular flange is formed at an opening of the lower end of the reaction tube 2, and at openings of the upper and lower ends of the manifold 3, respectively. In addition, a sealing member 4 such as an O-ring is interposed between the flange of the lower end of the reaction tube 2 and the flange of the upper end of the manifold 3, and thus a portion between the reaction tube 2 and the manifold 3 is hermetically sealed.

A processing chamber 7, in which a boat 6 as a substrate holder that holds plural sheets of wafers 5 that are substrates, is accommodated is defined at the inside of the reaction tube 2 and the manifold 3. The boat 6 is configured to be loaded into the processing chamber 7 from a lower side by a boat elevator 8 as an elevation mechanism of the substrate holder.

In addition, the boat 6 is configured to be mounted over a sealing cap 11 via a boat support base 9 as a support body and to hold plural sheets (for example, approximately 50 to 150 sheets) of wafers 5 in multi stages with a predetermined pitch interval at an approximately horizontal state. The maximum outer diameter of the boat 6 in which the wafers 5 are loaded is set to be smaller than inner diameters of the reaction tube 2 and the manifold 3.

The sealing cap 11 is a circular member that is formed from a metal such as SUS, and is configured to come into contact with the lower end of the manifold 3 from a lower side in the vertical direction. Therefore, when the boat elevator 8 is lifted up, the inside of the processing chamber 7 is hermetically sealed by the sealing member 12 that is interposed between the flange of the lower end of the manifold 3 and the sealing cap 11. In addition, when the sealing cap 11 is made to vertically move by the boat elevator 8, the boat 6 may be conveyed to the inside or outside of the processing chamber 7.

In addition, a rotating mechanism 13 is provided at a lower side of the sealing cap 11, and a rotary axis 14 of the rotating mechanism 13 penetrates through the sealing cap 11 and is connected to the boat 6. The rotary axis 14 is configured to rotate the boat 6 holding the wafers 5 while maintaining the airtightness of the processing chamber 7. Processing uniformity of the wafer 5 may be improved by rotating the boat 6.

A heater 15 as a circular heating portion is provided concentrically with the reaction tube 2 at the outer circumference of the reaction tube 2, and is configured to heat the wafers 5 that are loaded inside the processing chamber 7 at a predetermined temperature. The heater 15 is vertically supported by a heater base 16 as a holding plate, and the heater base 16 is fixed to the manifold 3.

In addition, similarly to multi-hole nozzles 17, 18, and 19 to be described later, a temperature sensor 21 as a temperature detector, which is formed in an L-shaped form along an inner wall of the reaction tube 2, is provided inside the reaction tube 2. When a state of power supply to the heater 15 is adjusted on the basis of temperature information that is detected by the temperature sensor 21, a temperature inside the processing chamber 7 has a desired temperature distribution.

The multi-hole nozzles 17, 18, and 19, which have an L-shaped form including a vertical portion and a horizontal portion, are provided to the manifold 3. The vertical portion of each of the multi-hole nozzles 17, 18, and 19 is vertically disposed along an inner wall of the processing chamber 7 and a lamination direction of the wafers 5. The horizontal portion of each of the multi-hole nozzles 17, 18, and 19 penetrates through a side wall of the manifold 3.

Plural gas supply ports 22, 23, and 24 are provided in side surfaces of the vertical portions of the multi-hole nozzles 17, 18, and 19 with a predetermined interval in the vertical direction, respectively. The gas supply ports 22, 23, and 24 are opened between the laminated wafers 5 in a state opposite to approximately the center of the processing chamber 7, that is, in a state opposite to approximately the center of the wafers 5 that are loaded in the processing chamber 7, respectively, and thus gases that are supplied from the gas supply ports 22, 23, and 24 are sprayed toward approximately the center of the inside of the processing chamber 7. In addition, an opening diameter of the gas supply ports 22, 23, and 24 may be the same over the lower portion to the upper portion thereof, or may increase gradually from the lower portion to the upper portion.

In addition, as shown in FIG. 8, the multi-hole nozzle 17 is provided at a position adjacent to the multi-hole nozzles 18 and 19, but in FIG. 7, for convenience, the multi-hole nozzle 17 is indicated at right position on paper that is opposite to the multi-hole nozzles 18 and 19.

An oxygen-containing gas supply pipe 25, which supplies, as an oxygen (O)-containing gas (an oxidant) such as a mixed gas of water vapor (H₂O), ozone (O₃), N₂O, oxygen (O₂), and hydrogen (H₂), and oxygen (O₂) plasma, for example, an H₂O gas, is connected to an upstream end (an end of the horizontal portion) of the multi-hole nozzle 17. An NH₃ gas supply source (not shown), a mass flow controller that is a flow rate control mechanism, and a valve 27 that is an on-off valve are provided to the oxygen-containing gas supply pipe 25 in that order from an upstream side.

An inert gas supply pipe 28, which supplies a carrier gas and a purge gas, for example, an inert gas such as a nitrogen (N₂) gas, a helium (He) gas, a neon (Ne) gas, and an argon (Ar) gas, is connected to a downstream side of the valve 27. An inert gas supply source (not shown), an inert gas mass flow controller (not shown), and a valve 29 are provided to the inert gas supply pipe 28 in that order from an upstream side. When the valve 27 is opened and the valve 29 is opened, an H₂O gas of which flow rate is controlled by the mass flow controller is supplied to the inside of the processing chamber 7 together with the inert gas.

In addition, when the valve 27 is closed and the valve 29 is opened, an inert gas as a purge gas of which flow rate is controlled by an inert gas mass flow controller (not shown) is supplied to the inside of the processing chamber 7. When the inert gas is supplied to the inside of the processing chamber 7, for example, an H₂O gas and the like, which remain inside the processing chamber 7 after termination of the H₂O gas supply, is removed. In addition, another gas that is supplied to the inside of the processing chamber 7 is prevented from flowing to the inside of the oxygen-containing gas supply pipe 25. In addition, a purge gas supply pipe that supplies the purge gas and a carrier gas supply pipe that supplies the carrier gas may be provided independently from each other.

In addition, the oxygen-containing gas supply pipe 25, the mass flow controller, the valve 27, the inert gas supply pipe 28, the inert gas mass flow controller (not shown), the valve 29, the multi-hole nozzle 17, and the gas supply port 22 make up the oxygen-containing gas supply system that supplies an oxygen-containing gas to the inside of the processing chamber 7. In addition, the inert gas supply pipe 28, the inert gas mass flow controller (not shown), the oxygen-containing gas supply pipe 25, the multi-hole nozzle 17, and the gas supply port 22 make up a first inert gas supply system that supplies the inert gas to the inside of the processing chamber 7.

In addition, a Zn-containing gas supply pipe 31, which supplies a DEZ gas obtained by vaporizing DEZ (Diethyl zinc, Zn(CH₂CH₃)₂) that is a Zn-containing raw material as a first raw material, is connected to an upstream end (an end of the horizontal portion) of the multi-hole nozzle 18. In addition, in this example, a bubbling method is adopted. In the bubbling method, a DEZ gas, which is obtained by supplying an inert gas such as a nitrogen (N₂) gas, a helium (He) gas, a neon (Ne) gas, and an argon (Ar) gas into liquid DEZ, is supplied to the inside of the processing chamber 7 together with the carrier gas.

A carrier gas supply pipe 33, which supplies the carrier gas via a DEZ container 32, is provided on an upstream side of the Zn-containing gas supply pipe 31. A carrier gas supply source (not shown), a mass flow controller 34, a valve 35, and the DEZ container 32 are provided to the carrier gas supply pipe 33 in that order from an upstream side. A liquid of DEZ is stored in the DEZ container 32, and a downstream end of the carrier gas supply pipe 33 is immersed in the liquid of DEZ.

An upstream end of the Zn-containing gas supply pipe 31 is disposed at an upper side of a DEZ liquid surface of the DEZ container 32, and a valve 36 is provided on a downstream side of the Zn-containing gas supply pipe 31. In addition, a pipe heater 37 is provided to the Zn-containing gas supply pipe 31, and thus the pipe heater 37 may maintain the Zn-containing gas supply pipe 31 to a temperature of, for example, approximately 50 to 60° C. When the valve 35 is opened, the carrier gas of which flow rate is controlled by the mass flow controller 34 is supplied to the DEZ container 32, and thus a DEZ gas is generated. In addition, when the valve 36 is further opened, the DEZ gas may be supplied to the inside of the processing chamber 7 together with the carrier gas.

In addition, the inside of the DEZ container 32 may be heated by a heater (not shown). When a heating temperature is adjusted by the heater, the generation of the DEZ gas is promoted or suppressed, and thus a supply flow rate of the DEZ gas to the inside of the processing chamber 7 may be controlled.

In addition, an upstream end of a gas exhaust pipe 38 is connected to the Zn-containing gas supply pipe 31 on upstream side thereof in relation to the valve 36, and a valve 39 is provided in a midway portion of the gas exhaust pipe 38. A downstream end of the gas exhaust pipe 38 is connected to an exhaust pipe 41 to be described later on a downstream side thereof in relation to an APC (Auto Pressure Controller) valve 42, and thus when the valve 39 is opened, the DEZ gas may be exhausted without flowing through the processing chamber 7.

In addition, a downstream end of an inert gas supply pipe 43 that supplies an inert gas is connected to the Zn-containing gas supply pipe 31 on a downstream side thereof in relation to the valve 36. An inert gas supply source (not shown), an inert gas mass flow controller (not shown), and a valve 44 are provided to the inert gas supply pipe 43 in that order from an upstream side. When the valve 44 is opened, an inert gas as a purge gas of which flow rate is controlled by the inert gas mass flow controller may be supplied to the inside of the processing chamber 7. When the inert gas is supplied to the inside of the processing chamber 7, for example, the DEZ gas and the like, which remain inside the processing chamber 7 after termination of the DEZ gas supply, is removed. In addition, another gas that is supplied to the inside of the processing chamber 7 is prevented from flowing to the inside of the Zn-containing gas supply pipe 31.

In addition, the carrier gas supply pipe 33, the mass flow controller 34, the valve 35, the Zn-containing gas supply pipe 31, the valve 36, the multi-hole nozzle 18, and the gas supply port 23 make up a Zn-containing gas supply system that supplies the DEZ gas to the inside of the processing chamber 7. In addition, the inert gas supply pipe 43, the inert gas mass flow controller (not shown), the valve 44, the Zn-containing gas supply pipe 31, the multi-hole nozzle 18, and the gas supply port 23 make up an inert gas supply system that supplies the inert gas as a purge gas to the inside of the processing chamber 7.

A Ga-containing gas supply pipe 45, which supplies a TMGa gas that is obtained by vaporizing TMGa (Trimethyl gallium ((CH₃)₃Ga) that is a Ga-containing raw material as a second raw material, is connected to an upper end (an end of the horizontal portion) of the multi-hole nozzle 19. In addition, in this example, a bubbling method is adopted similarly to the DEZ gas. In the bubbling method, a TMGa gas, which is obtained by supplying an inert gas into liquid TMGa, is supplied to the inside of the processing chamber 7 together with the carrier gas.

A carrier gas supply pipe 47, which supplies a carrier gas via a TMGa container 46, is provided on an upstream side of the Ga-containing gas supply pipe 45. A carrier gas supply source (not shown), a mass flow controller 48, a valve 49, and the TMGa container 46 are provided to the carrier gas supply pipe 47 in that order from an upstream side. A liquid of TMGa is stored in the TMGa container 46, and a downstream end of the carrier gas supply pipe 47 is immersed in the liquid of TMGa.

An upstream end of the Ga-containing gas supply pipe 45 is disposed at an upper side of a TMGa liquid surface of the TMGa container 46, and a valve 51 is provided on a downstream side of the Ga-containing gas supply pipe 45. In addition, a second pipe heater 52 is provided to the Ga-containing gas supply pipe 45, and thus the second pipe heater 52 may maintain the Ga-containing gas supply pipe 45 to a temperature of, for example, approximately 40° C. When the valve 49 is opened, a carrier gas of which flow rate is controlled by the mass flow controller 48 is supplied to the inside of the TMGa container 46, and thus a TMGa gas is generated. In addition, the valve 51 is further opened, the TMGa gas may be supplied to the inside of the processing chamber 7 together with the carrier gas.

In addition, the inside of the TMGa container 46 may be heated by a heater (not shown). When a heating temperature is adjusted by the heater, the generation of the TMGa gas is promoted or suppressed, and thus a supply flow rate of the TMGa gas to the inside of the processing chamber 7 may be controlled.

In addition, an upstream end of a gas exhaust pipe 53 is connected to the Ga-containing gas supply pipe 45 on an upstream side thereof in relation to the valve 51, and a valve 54 is provided in a midway portion of the gas exhaust pipe 53. A downstream end of the gas exhaust pipe 53 is connected to the exhaust pipe 41 on a downstream side thereof in relation to the APC valve 42, and thus when the valve 54 is opened, the TMGa gas may be exhausted without flowing through the processing chamber 7.

In addition, a downstream end of an inert gas supply pipe 55 that supplies an inert gas is connected to the Ga-containing gas supply pipe 45 on a downstream side thereof in relation to the valve 51. An inert gas supply source (not shown), and an inert gas mass flow controller (not shown), a valve 56 are provided to the inert gas supply pipe 55 in that order from an upstream side. When the valve 56 is opened, an inert gas as a purge gas of which flow rate is controlled by the inert gas mass flow controller may be supplied to the inside of the processing chamber 7. When the inert gas is supplied to the inside of the processing chamber 7, for example, the TMGa gas and the like, which remain inside the processing chamber 7 after termination of the TMGa gas supply, is removed. In addition, another gas that is supplied to the inside of the processing chamber 7 is prevented from flowing to the Ga-containing gas supply pipe 45.

In addition, the carrier gas supply pipe 47, the carrier gas supply source (not shown), the mass flow controller 48, the valve 49, the TMGa container 46, the Ga-containing gas supply pipe 45, the valve 51, the multi-hole nozzle 19, and the gas supply port 24 make up a Ga-containing gas supply system that supplies the TMGa gas to the inside of the processing chamber 7. In addition, the inert gas supply pipe 55, the inert gas mass flow controller (not shown), the valve 56, the Ga-containing gas supply pipe 45, the multi-hole nozzle 19, and the gas supply port 24 make up an inert gas supply system that supplies the inert gas as a purge gas to the inside of the processing chamber 7.

The exhaust pipe 41 is connected to a side wall of the manifold 3. A pressure sensor 57 as a pressure detector that detects a pressure inside the processing chamber 7, the APC valve 42 as a pressure adjustor, and a vacuum pump 58 as an evacuation device are provided to the exhaust pipe 41 in that order form an upstream side.

The APC valve 42 is an on-off valve which may perform evacuation and stoppage of exhaustion by carrying out on and off of a plate, and in which an opening degree of the plate may be adjusted. When the opening degree of the APC valve 42 is adjusted on the basis of pressure information detected by the pressure sensor 57 while operating the vacuum pump 58, the inside of the processing chamber 7 may be set to a desired pressure.

In addition, the exhaust pipe 41, the pressure sensor 57, the APC valve 42, and the vacuum pump 58 make up an exhaust system that exhausts an atmosphere inside the processing chamber 7.

In addition, a controller 59 as a control system is connected to the mass flow controllers 26, 34, and 48, the APC valve 42, the valves 27, 29, 35, 36, 39, 44, 49, 51, 54, and 56, the temperature sensor 21, the heater 15, the pressure sensor 57, the vacuum pump 58, the rotating mechanism 13, the boat elevator 8, and the like. The controller 59 controls a flow rate adjusting operation of the mass flow controllers 26, 34, and 48, on and off operation of the valves 27, 29, 35, 36, 39, 44, 49, 51, 54, and 56, on and off operation and a pressure adjusting operation of the APC valve 42, a temperature detecting operation of the temperature sensor 21, a temperature adjusting operation of the heater 15, a pressure detecting operation of the pressure sensor 57, activation and stopping of the vacuum pump 58, a rotational velocity adjusting of the rotating mechanism 13, and vertical movement of the boat elevator 8.

### (2) Substrate Processing Process

Next, description will be made with respect to a substrate processing process of forming a gate electrode of a MOSFET on a wafer as a substrate by using the processing furnace of the above-described substrate processing apparatus as one process of semiconductor device manufacturing processes relating to the third preferred embodiment of the invention. In addition, in the following description, the operation of the respective portions making up the substrate processing apparatus is controlled by the controller 59. Here, plural kinds of processing gases are alternately supplied to the wafer 200 without being mixed, and a thin film is formed on the wafer 200. At this time, the film thickness of the thin film that is formed may be controlled by controlling the number of supply times of the processing gases. For example, when a film forming rate is 0.1 nm/cycle, a thin film of 2 nm may be formed by performing 20 cycles.

Hereinafter, description will be made with respect to a process of forming the film 316, which has a laminated structure in which the plural ZnO films 312 and the plural Ga₂O₃ films 314 are alternately laminated, on an HfSiOx film as the gate insulating film 302 that is formed in advance on the wafers 5 as a substrate. In addition, each of the ZnO films 312 is formed by alternately supplying a first raw material gas obtained by vaporizing a first raw material (Diethyl Zinc (Zn(CH₂CH₃)₂, DEZ)) and a reaction gas (water vapor (H₂O)) to the inside of the processing chamber 201 that accommodates the wafers 5. In addition, each of the Ga₂O₃ film 314 is formed by alternately supplying a second raw material gas obtained by vaporizing a second raw material (Trimethyl gallium ((CH₃)₃Ga, TMGa)) and the reaction gas (water vapor (H₂O)) to the inside of the processing chamber 201 that accommodates the wafers 5.

Substrate Loading Process (Step S310)

First, plural sheets (for example, 100 sheets) of wafers 5 are loaded in the boat 6 (wafer charging), and the boat 6 is lifted up by the boat elevator 8 and is loaded to the inside of the processing chamber 7 (boat loading). At this time, the inside of the processing chamber 7 is hermetically sealed by sealing a lower end of the manifold 3 with the sealing cap 11 via the sealing member 12. In addition, at this state, it is preferable to continuously supply the inert gas such as the N₂ gas to the inside of the processing chamber 7 by opening the valves 29, 44, and 56.

Pressure Adjusting Process (Step S320) and Temperature Adjusting Process (Step S330)

Subsequently, the valves 29, 44, and 56 are closed, and the inside of the processing chamber 7 is evacuated by activating the vacuum pump 58. In addition, a state of power supply to the heater 15 is feedback-controlled on the basis of temperature information from the temperature sensor 21, and thus a temperature inside the processing chamber 7 is adjusted so that a temperature of the wafers 5 becomes 50 to 200° C., for example, 100° C. Then, the boat 6, that is, the wafers 5 are rotated by the rotating mechanism 13.

In addition, concurrently with the above-described process, the valve 35 is opened with the valve 36 closed, and thus the carrier gas is supplied to the inside of the DEZ container 32 while controlling a flow rate by the mass flow controller 34, whereby a Zn-containing liquid raw material, for example, a DEZ gas that is obtained by vaporizing DEZ is generated in advance. At this time, when the vacuum pump 58 is operated, and the valve 39 is opened with the valve 36 closed, the DEZ gas may bypass the processing chamber 7 and is exhausted without being supplied to the inside of the processing chamber 7.

In addition, at this time, the valve 49 is opened with the valve 51 closed, and the carrier gas is supplied to the container 46 while controlling a flow rate thereof by the mass flow controller 48, whereby a Ga-containing liquid raw material, for example, a TMGa gas that is obtained by vaporizing TMGa is generated in advance. At this time, when the vacuum pump 58 is operated, and the valve 54 is opened with the valve 51 closed, the TMGa gas may bypass the processing chamber 7 and is exhausted without being supplied to the inside of the processing chamber 7.

In a supply method by bubbling, since a predetermined time is necessary in order to enter a state in which the DEZ gas or the TMGa gas is stably generated, when supply of the DEZ gas or the TMGa gas is initiated at an initial generation stage, the supply becomes unstable. Therefore, in the present example, the DEZ gas or the TMGa gas is generated in advance to enter a state in which this gas may be stably supplied, and then the on and off of the valves 36, 39, 51, and 54 are switched to switch a flow path of the DEZ gas and the TMGa gas. According to this configuration, supply initiation of the DEZ gas and the TMGa gas to the inside of the processing chamber 7 and supply stopping thereof may be stably and quickly performed.

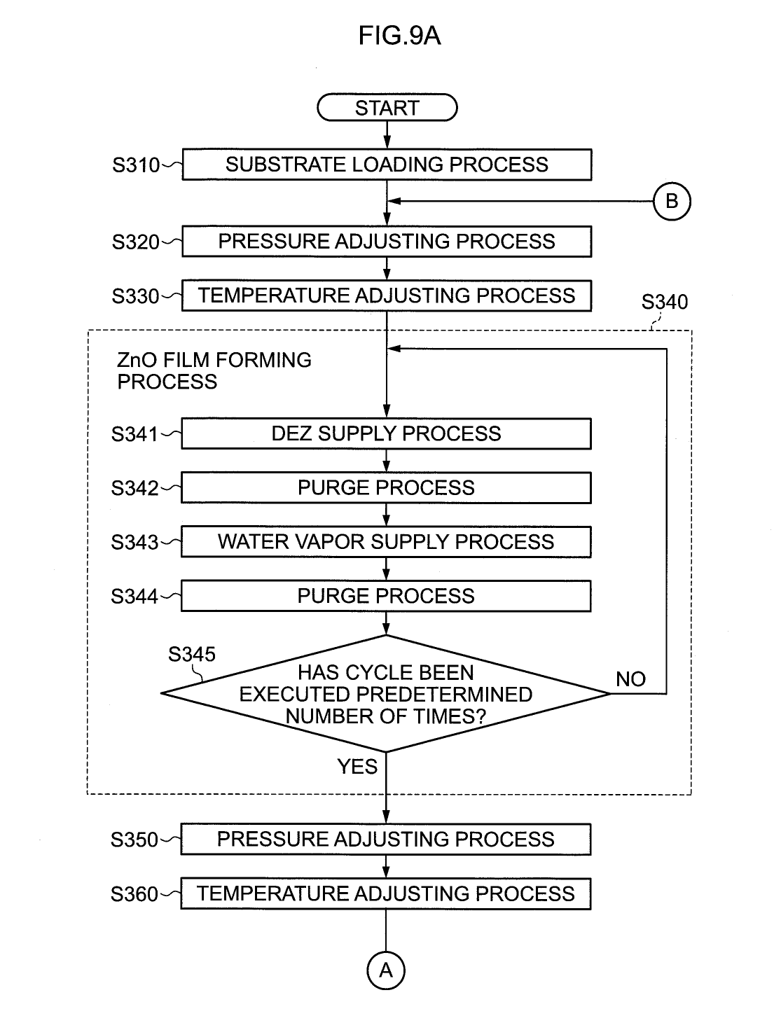

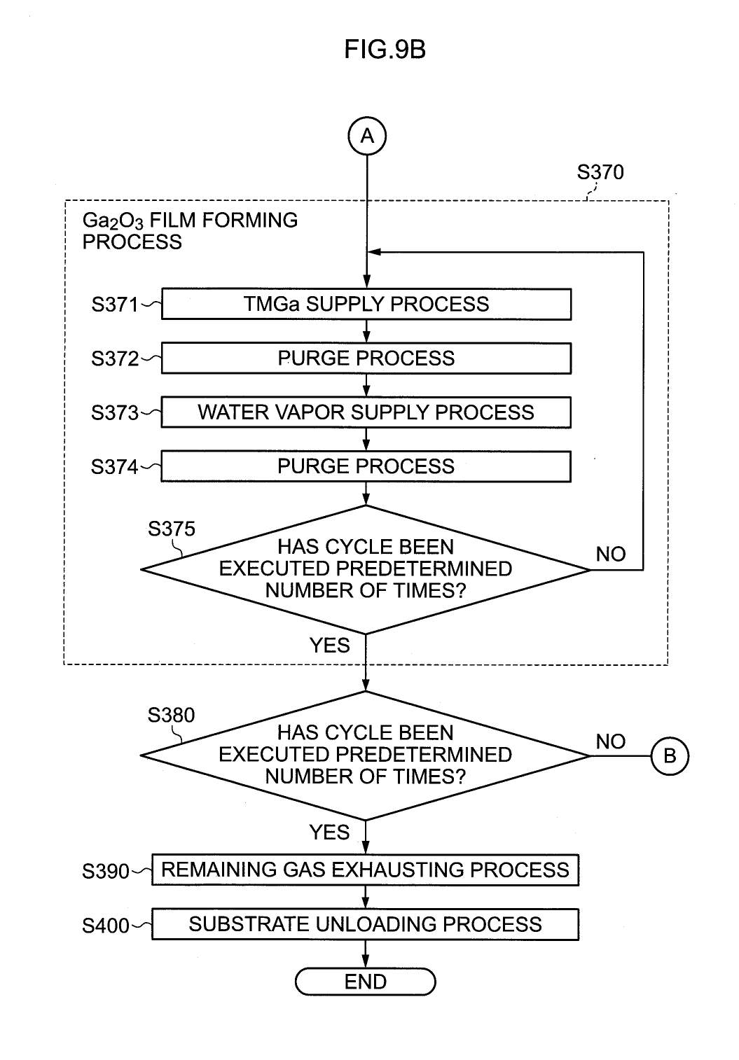

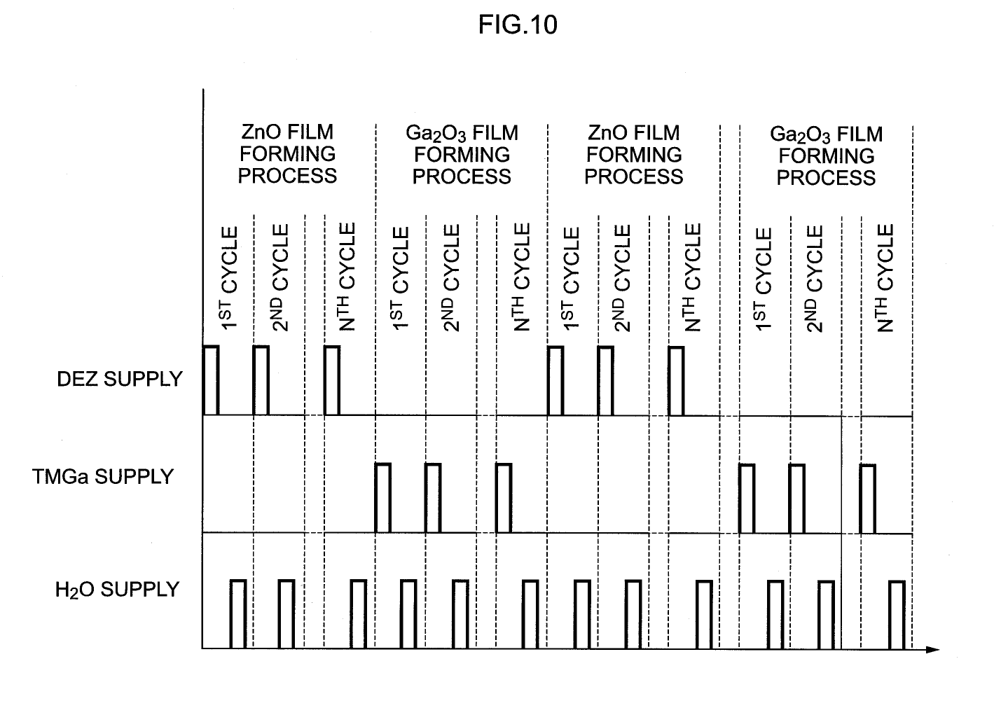

Next, a film forming process of generating a thin film on the wafers 5 in the processing chamber 7 is performed. FIGS. 9A and 9B shows a sequence diagram in the film forming process of the third embodiment, and FIG. 10 shows a timing chart in the film forming process of the third embodiment.

ZnO Film Forming Process (Step S340)

Next, the DEZ gas and the H₂O gas are supplied to the inside of the processing chamber 7 and thus the ZnO film is formed on the HfSiOx film as a gate insulating film that is formed in advance on the wafers 5. In the ZnO film forming process, the following steps are sequentially performed.

DEZ Supply Process (Step S341)

The DEZ gas is supplied as a Zn-containing gas to the inside of the processing chamber 7 from the Zn-containing gas supply pipe 31 via the gas supply port 23 of the multi-hole nozzle 18. Specifically, the valve 39 is closed and the valve 36 is opened, and thus the supply of the vaporized DEZ gas together with the carrier gas to the inside of the processing chamber 7 from the Zn-containing gas supply pipe 31 is initiated. At this time, an opening degree of the APC valve 42 is adjusted, and a pressure inside the processing chamber 7 is maintained within a range of 10 to 1,000 Pa, for example, 20 Pa. For example, a supply flow rate of the DEZ gas is set to be within a range of 0.2 to 10 g/min. For example, a supply time of the DEZ gas is set to be within a range of 30 to 300 seconds. After the passage of a predetermined time, the valve 36 is closed and the valve 39 is opened to stop the supply of the DEZ gas.

The DEZ gas that is supplied to the inside of the processing chamber 7 is supplied to the wafers 5 and is exhausted from the exhaust pipe 41. At this time, gases that are present in the processing chamber 7 include only the DEZ gas and the inert gas such as N₂ gas and an oxygen-containing gas is not present, and thus a Zn-containing layer is formed on the HfSiOx film as the gate insulating film that is formed on the wafers 5 in advance.

In addition, during supply of the DEZ gas to the inside of the processing chamber 7, when the valve 29 of the inert gas supply pipe 28 that is connected to the oxygen-containing gas supply pipe 25 is opened to cause the inert gas such as an N₂ gas to flow, inflow of the DEZ gas to the inside of the oxygen-containing gas supply pipe 25 may be prevented. In addition, when the valve 56 of the inert gas supply pipe 55 that is connected to the Ga-containing gas supply pipe 45 is opened to cause the inert gas such as an N₂ gas to flow, inflow of the DEZ gas to the inside of the Ga-containing gas supply pipe 45 may be prevented.

Purge Process (Step S342)

After the valve 36 is closed to stop the supply of the DEZ gas to the inside of the processing chamber 7, the APC valve 42 is opened and the processing chamber 7 is exhausted in order for the pressure inside thereof to be, for example, 1 Pa or less, and thus the DEZ gas, reaction products, and the like that remain inside the processing chamber 7 are removed. At this time, when the inert gas such as N₂ gas is supplied to the inside of the processing chamber 7 from the carrier gas supply pipes 28, 43, and 55, respectively, to purge the processing chamber 7, an effect of removing the remaining gas from the inside of the processing chamber 7 may be more increased. After the passage of a predetermined time, the valves 29, 44, and 56 are closed, and the purge process is terminated.

Water Vapor Supply Process (Step S343)

Next, the H₂O gas is supplied as an oxygen-containing gas to the inside of the processing chamber 7 from the oxygen-containing gas supply pipe 25 via the gas supply port 22 of the multi-hole nozzle 17. Specifically, the valve 27 and the valve 29 are opened, and thus supply of the H₂O gas from the oxygen-containing gas supply pipe 25 to the inside of the processing chamber 7 is initiated while mixing the N₂ gas and the H₂O gas with each other. At this time, the opening degree of the APC valve 42 is adjusted to maintain the pressure inside the processing chamber 7 within a range of 10 to 1,000 Pa, for example, at 20 Pa. For example, a supply flow rate of the H₂O gas is set to be within a range of 50 to 500 sccm. For example, a supply time of the H₂O gas is set to be within a range of 10 to 100 seconds. After the passage of a predetermined time, the valve 27 is closed to stop the supply of the H₂O gas.

The H₂O gas that is supplied to the inside of the processing chamber 7 is supplied to the wafers 5 and is exhausted from the exhaust pipe 41. At this time, gases that are present in the processing chamber 7 include only the H₂O gas and the N₂ gas and a Zn-containing gas is not present, and thus the gases that are present in the processing chamber 7 react with the Zn-containing layer that is formed on the HfSiOx film as the gate insulating film that is formed on the wafers 5 in advance, whereby a ZnO layer is formed.

In addition, during supply of the H₂O gas to the inside of the processing chamber 7, when the valve 44 of the inert gas supply pipe 43 that is connected to the Zn-containing gas supply pipe 31 is opened to cause the inert gas such as an N₂ gas to flow, inflow of the H₂O gas to the inside of the Zn-containing gas supply pipe 31 may be prevented. In addition, when the valve 56 of the inert gas supply pipe 55 that is connected to the Ga-containing gas supply pipe 45 is opened to cause the inert gas such as an N₂ gas to flow, inflow of the H₂O gas to the inside of the Ga-containing gas supply pipe 45 may be prevented.

Purge Process (Step S344)

After the valve 27 is closed to stop the supply of the H₂O gas to the inside of the processing chamber 7, the APC valve 42 is opened and the processing chamber 7 is exhausted in order for the pressure inside thereof to be, for example, 1 Pa or less, and thus the H₂O gas, reaction products, and the like that remain inside the processing chamber 7 are removed. At this time, when the inert gas such as N₂ gas is supplied to the inside of the processing chamber 7 from the carrier gas supply pipes 28, 43, and 55, respectively, to purge the processing chamber 7, an effect of removing the remaining gas from the inside of the processing chamber 7 may be more increased. After the passage of a predetermined time, the valves 29, 44, and 56 are closed, and the purge process is terminated.

Predetermined Number of Times Executing Process (Step S345)

Step S341 to step S344 are set as one cycle, and this cycle is executed in a predetermined number of times (n cycles) to form the ZnO film having a desired film thickness on the HfSiOx film that is formed in advance on the wafers 5.

Pressure Adjusting Process (Step S350) and Temperature Adjusting Process (Step S360)

Subsequently, the valves 29, 44, and 56 are closed, and the inside of the processing chamber 7 is evacuated by activating the vacuum pump 58. In addition, a state of power supply to the heater 15 is feedback-controlled on the basis of temperature information from the temperature sensor 21, and thus a temperature inside the processing chamber 7 is adjusted so that a temperature of the wafers 5 becomes 50 to 200° C., for example, 100° C. In a case in which the pressure adjustment and the temperature adjustment are unnecessary, steps S350 and S360 are omitted and a Ga₂O₃ film forming process (step S370) to be described later is performed.

Ga₂O₃ Film Forming Process (Step S370)

Next, the TMGa gas and the H₂O gas are supplied to the inside of the processing chamber 7, and thus a GaO film is formed on the HfSiOx film as the gate insulating film that is formed on the wafers 5 in advance. In the GaO film forming process, the following steps are sequentially performed.

TMGa Supply Process (Step S371)

The TMGa gas is supplied as a Ga-containing gas to the inside of the processing chamber 7 from the Ga-containing gas supply pipe 45 via the gas supply port 24 of the multi-hole nozzle 19. Specifically, the valve 54 is closed and the valve 51 is opened, and thus the supply of the vaporized TMGa gas together with the carrier gas to the inside of the processing chamber 7 from the Ga-containing gas supply pipe 45 is initiated. At this time, an opening degree of the APC valve 42 is adjusted, and a pressure inside the processing chamber 7 is maintained within a range of 10 to 100 Pa, for example, 20 Pa. For example, a supply flow rate of the TMGa gas is set to be within a range of 0.2 to 10 g/min. For example, a supply time of the TMGa gas is set to be within a range of 30 to 300 seconds. After the passage of a predetermined time, the valve 51 is closed and the valve 56 is opened to stop the supply of the TMGa gas.

The TMGa gas that is supplied to the inside of the processing chamber 7 is supplied to the wafers 5 and is exhausted from the exhaust pipe 41. At this time, gases that are present in the processing chamber 7 include only the TMGa gas and the inert gas such as N₂ gas and an oxygen-containing gas is not present, and thus a Ga-containing layer is formed on the HfSiOx film as the gate insulating film that is formed on the wafers 5 in advance.

In addition, during supply of the TMGa gas to the inside of the processing chamber 7, when the valve 29 of the inert gas supply pipe 28 that is connected to the oxygen-containing gas supply pipe 25 is opened to cause the inert gas such as an N₂ gas to flow, inflow of the TMGa gas to the inside of the oxygen-containing gas supply pipe 25 may be prevented. In addition, when the valve 44 of the inert gas supply pipe 43 that is connected to the Zn-containing gas supply pipe 31 is opened to cause the inert gas such as an N₂ gas to flow, inflow of the TMGa gas to the inside of the Zn-containing gas supply pipe 31 may be prevented.

Purge Process (Step S372)

After the valve 51 is closed to stop the supply of the TMGa gas to the inside of the processing chamber 7, the APC valve 42 is opened and the processing chamber 7 is exhausted in order for the pressure inside thereof to be, for example, 1 Pa or less, and thus the TMGa gas, reaction products, and the like that remain inside the processing chamber 7 are removed. At this time, when the inert gas such as N₂ gas is supplied to the inside of the processing chamber 7 from the carrier gas supply pipes 28, 43, and 55, respectively, to purge the processing chamber 7, an effect of removing the remaining gas from the inside of the processing chamber 7 may be more increased. After the passage of a predetermined time, the valves 29, 44, and 56 are closed, and the purge process is terminated.

Water Vapor Supply Process (Step S373)

Next, the H₂O gas is supplied as an oxygen-containing gas to the inside of the processing chamber 7 from the oxygen-containing gas supply pipe 25 via the gas supply port 22 of the multi-hole nozzle 17. Specifically, the valve 27 and the valve 29 are opened, and thus supply of the H₂O gas from the oxygen-containing gas supply pipe 25 to the inside of the processing chamber 7 is initiated while mixing the N₂ gas and the H₂O gas with each other. At this time, the opening degree of the APC valve 42 is adjusted to maintain the pressure inside the processing chamber 7 within a range of 10 to 100 Pa, for example, at 20 Pa. For example, a supply flow rate of the H₂O gas is set to be within a range of 50 to 500 sccm. For example, a supply time of the H₂O gas is set to be within a range of 10 to 100 seconds. After the passage of a predetermined time, the valve 27 is closed to stop the supply of the H₂O gas.

The H₂O gas that is supplied to the inside of the processing chamber 7 is supplied to the wafers 5 and is exhausted from the exhaust pipe 41. At this time, gases that are present in the processing chamber 7 include only the H₂O gas and the N₂ gas and a Ga-containing gas is not present, and thus the gases that are present in the processing chamber 7 react with the Ga-containing layer that is formed on the HfSiOx film as the gate insulating film that is formed on the wafers 5 in advance, whereby a Ga₂O₃ layer is formed.

In addition, during supply of the H₂O gas to the inside of the processing chamber 7, when the valve 44 of the inert gas supply pipe 43 that is connected to the Zn-containing gas supply pipe 31 is opened to cause the inert gas such as an N₂ gas to flow, inflow of the H₂O gas to the inside of the Zn-containing gas supply pipe 31 may be prevented. In addition, when the valve 56 of the inert gas supply pipe 55 that is connected to the Ga-containing gas supply pipe 45 is opened to cause the inert gas such as an N₂ gas to flow, inflow of the H₂O gas to the inside of the Ga-containing gas supply pipe 45 may be prevented.

Purge Process (Step S374)

After the valve 27 is closed to stop the supply of the H₂O gas to the inside of the processing chamber 7, the APC valve 42 is opened and the processing chamber 7 is exhausted in order for the pressure inside thereof to be, for example, 1 Pa or less, and thus the H₂O gas, reaction products, and the like that remain inside the processing chamber 7 are removed. At this time, when the inert gas such as N₂ gas is supplied to the inside of the processing chamber 7 from the carrier gas supply pipes 28, 43, and 55, respectively, to purge the processing chamber 7, an effect of removing the remaining gas from the inside of the processing chamber 7 may be more increased. After the passage of a predetermined time, the valves 29, 44, and 56 are closed, and the purge process is terminated.

Predetermined Number of Times Executing Process (Step S375)

Step S371 to step S374 are set as one cycle, and this cycle is executed in a predetermined number of times (n cycles) to form the Ga₂O₃ film having a desired film thickness on the HfSiOx film that is formed on the wafers 5.

Predetermined Number of Times Executing Process (Step S380)

When the ZnO film forming process (step S340) and the Ga₂O₃ film forming process (step S370) are performed in a predetermined number of times, a GZO film, which has a laminated structure in which plural ZnO films and plural Ga₂O₃ films are alternately laminated, is formed on the HfSiOx film as the gate insulating film that is formed on the wafers 5 in advance.

Remaining Gas Removing Process (Step S390)

After the GZO film having the laminated structure in which the plural ZnO films and the plural Ga₂O₃ films are alternately laminated, the inside of the processing chamber 7 is evacuated, and then the valves 29, 44, and 56 are opened to supply the N₂ gas to the inside of the processing chamber 7. The N₂ gas that is supplied is exhausted to the exhaust pipe 41. According to this configuration, gases or reaction byproducts that remain inside the processing chamber 7 are removed and the inside of the processing chamber 7 is purged by the N₂ gas.

Substrate Unloading Process (Step S400)

Then, in the order opposite to the order illustrated in the above-described substrate loading process (step S310), after the GZO film having the laminated structure in which the plural ZnO films having the predetermined film thickness and the plural Ga₂O₃ films having the predetermined film thickness are alternately laminated is formed on the wafers 5, the wafers 5 are unloaded from the processing chamber 7, whereby the substrate processing process (batch processing) according to this embodiment is terminated.

According to the third embodiment, the substrate processing process is performed using the vertical type device, and thus plural sheets of substrate may be processed at a time, whereby throughput may be improved.

In addition, even in the case in which the conductive oxide film is used for the capacitor electrode of the DRAM as the above-described second preferred embodiment of the invention, the vertical type device described in the third embodiment is applicable.

### Fourth Embodiment

Next, a fourth preferred embodiment of the invention will be described. In the third embodiment, description was made with respect to an example in which the GZO film is formed as the gate electrode by using the vertical type device as the substrate processing apparatus. However, this fourth embodiment is different from the third embodiment in that instead of the GZO film, a molybdenum oxide (MoOx (MoO₃ or the like)) film is formed in the fourth embodiment. The MoOx film is formed as a gate electrode or a capacitor electrode of a DRAM. In the following description, points that are different from the third embodiment will be mainly described. As a substrate processing apparatus, the same vertical type device as the third embodiment is used. Description of the same portions as the third embodiment will not be repeated.

Similarly to the third embodiment, plural raw material gases are alternately supplied to the inside of the processing chamber 7 to form the MoOx film on the wafers 5. As a molybdenum (Mo) raw material, for example, molybdenum hexacarbonyl (Mo(CO)₆) may be used, and as an oxygen-containing gas, for example, ozone (O₃) may be used. Here, Mo(CO)₆ that is an individual substance is put into a tank and heat at 90° C., and a flow rate control is performed at 100 to 500 sccm using a mass flow meter, which is provided downstream the tank, with low pressure difference. Then, Mo(CO)₆ is mixed with a carrier gas (N₂ or the like) of 1 to 5 slm and is the resultant mixed gas is supplied to the inside of the processing chamber 7 as a Mo gas. In addition, the O₃ gas is generated from O₂ by an ozonizer and is supplied to the inside of the processing chamber 7. At this time, the inside of the processing chamber 7 is heated at 100 to 170° C.

Specifically, the following MoOx film forming process is performed. The Mo(CO)₆ gas is supplied to the inside of the processing chamber 7, and thus a Mo-containing layer is formed on the wafers 5. Next, the Mo(CO)₆ gas and the like that remain inside the processing chamber 7 is removed by a purge process. Furthermore, when the O₃ gas is supplied to the inside of the processing chamber 7, the O₃ gas reacts with the Mo-containing layer, and thus a MoOx layer is formed on the wafers 5. When the MoOx film forming process is performed in a predetermined number of times (n cycles), the MoOx film having a desired film thickness is formed on the wafers 5.

In addition, in the above description, an example in which the vertical type device is used as the substrate processing apparatus is described. However, this embodiment is also applicable to other device types, and is applicable to, for example, the single wafer type device similar to the second embodiment.

### Fifth Embodiment

Next, a fifth preferred embodiment of the invention will be described. The fourth embodiment is similar to the third embodiment in that the MoOx film is formed by using the vertical type device as the substrate processing apparatus. However, the fourth embodiment and the fifth embodiment are different from each other in that in the fourth embodiment, as a method of forming a film, a method in which plural kinds of raw material gases are alternately supplied to form a Mo layer on the HfSiOx film as a gate insulating film that is formed in advance on the wafers 5, and then the Mo layer and the oxygen-containing gas are made to react with each other to form the MoO layer is used, but in the fifth embodiment, as a method of forming a film, a method in which one kind or two kinds of raw material gases are supplied to the inside of the processing chamber 7 that is heated, and the MoOx film is deposited with thermal decomposition reaction of the raw material gases. The MoOx film is formed as a gate electrode or a capacitor electrode of a DRAM. Hereinafter, points that are different from the fourth embodiment will be mainly described. Description of the same portions as the fourth embodiment will not be repeated.

In the fifth embodiment, the Mo(CO)₆ gas that is vaporized is mixed with the carrier gas (N₂) and the resultant mixed gas is supplied to the inside of the processing chamber 7 that is heated at 150 to 200° C. At this time, a MoOx layer is deposited on the wafers 5 by a thermal decomposition reaction of the Mo(CO)₆ gas. When the Mo(CO)₆ gas is supplied to the inside of the processing chamber 7 for a predetermined time, a MoOx film having a desired film thickness is formed on the wafers 5.

Here, description was made with respect to an example in which only the vaporized Mo(CO)₆ gas is used as a raw material gas, but the vaporized Mo(CO)₆ gas and approximately 500 sccm to 2 slm of oxygen (O₂) may be supplied simultaneously.

In the above description, an example in which the vertical type device is used as the substrate processing apparatus is described, but this embodiment is applicable to other device types. For example, this embodiment is applicable to the single wafer type device similar to the second embodiment.

For example, vanadium oxytriethoxide (VO(OC₂H₅)₃) or the like is possible. In addition, in the above description, an example in which the vertical type device is used as the substrate processing apparatus is described, but this embodiment is applicable to other device types. For example, this embodiment is applicable to the single wafer type device similar to the second embodiment.

### Sixth Embodiment

Next, a sixth preferred embodiment of the invention will be described. The fifth embodiment and the sixth embodiment are different from each other in that in the fifth embodiment, the vertical type device is used as the substrate processing apparatus, one kind or two kinds of raw material gases are supplied to the inside of the processing chamber 7 that is heated, and the MoOx film is formed by thermal decomposition reaction of the raw material gases, but in the sixth embodiment, a vanadium oxide (VxOy) film is formed instead of the MoOx film. Hereinafter, points that are different from the fifth embodiment will be mainly described. Description of the same portions as the fifth embodiment will not be repeated.

In the sixth embodiment, as a vanadium (Mo) raw material, for example, vanadium oxytriisopropoxide (C₉H₂₁O₄V) that is a liquid raw material may be used. Here, a tank into which C₉H₂₁O₄V is put is heated at approximately 80° C., and a flow rate control is performed at 100 to 500 sccm using a mass flow meter, which is provided downstream the tank, with low pressure difference. C₉H₂₁O₄V is mixed with 1 to 5 slm of carrier gas (N₂ or the like) and the resultant mixed gas is supplied to the inside of the processing chamber 7 as a C₉H₂₁O₄V gas. At this time, the inside of the processing chamber 7 is heated at 100 to 170° C. At this time, a vanadium oxide layer is deposited on the wafers 5 by thermal decomposition reaction of the C₉H₂₁O₄V gas. When the C₉H₂₁O₄V gas is supplied to the inside of the processing chamber 7 for a predetermined time, a vanadium oxide film having a desired film thickness is formed on the wafers 5.

In addition, in the above description, an example in which C₉H₂₁O₄V is used as the V raw material, but this embodiment is applicable to other V raw materials.

### Preferred Aspects of Present Invention

Hereinafter, preferred aspects of the present invention will be additionally stated.

Additional Statement 1

According to a preferred aspect of the present invention, there is provided a semiconductor device, including:

a gate insulating film or a capacitor insulating film that is formed on a semiconductor substrate; and

an electrode including a conductive oxide film that is formed to come into contact with the gate insulating film or the capacitor insulating film.

Additional Statement 2

According to another preferred aspect of the present invention, there is provided a method of manufacturing a semiconductor device, including:

loading a substrate to a processing chamber, a gate insulating film or a capacitor insulating film being formed on a surface of the substrate;

forming an electrode, which includes a conductive oxide film and to which an additive that modulates a work function of the conductive oxide film is added, on the substrate; and

unloading the substrate, on which the electrode is formed, from the processing chamber.

Additional Statement 3

In the method of manufacturing the semiconductor device according to Additional Statement 2, preferably, in the forming of the electrode, the work function of the conductive oxide film is modulated by adding the additive to the conductive oxide film.

Additional Statement 4

In the method of manufacturing the semiconductor device according to Additional Statement 3, preferably, in the forming of the electrode, the modulation of the work function of the conductive oxide film is controlled by controlling an amount of the additive with respect to the conductive oxide film so as to obtain a desired work function.

Additional Statement 5

In the method of manufacturing the semiconductor device according to Additional Statement 4, preferably, the additive is added by an amount of 5% to 15% with respect to the conductive oxide film.

Additional Statement 6

In the method of manufacturing the semiconductor device according to Additional Statement 3, preferably, the forming of the electrode includes;

forming the conductive oxide film on the substrate, and

adding the additive to the conductive oxide film that has been formed by the forming of the conductive oxide film.

Additional Statement 7

In the method of manufacturing the semiconductor device according to Additional Statement 6, preferably, in the forming of the electrode, the forming of the conductive oxide film and the adding of the additive are alternately performed plural times.

Additional Statement 8

In the method of manufacturing the semiconductor device according to Additional Statement 6, preferably, in the forming of the conductive oxide film, the conductive oxide film is formed by exposing the substrate to plural kinds of raw materials in an alternate manner in order for the plural kinds of raw materials not to be mixed with each other.

Additional Statement 9

In the method of manufacturing the semiconductor device according to Additional Statement 3, preferably, the additive is at least one oxide film for addition that is selected from the group consisting of a gallium oxide film, an aluminum oxide film and a tin oxide film.

Additional Statement 10

In the method of manufacturing the semiconductor device according to Additional Statement 9, preferably, in the adding of the additive, the oxide film for addition is formed by exposing the substrate to at least one raw material selected from the group consisting of a gallium-containing raw material, an aluminum-containing raw material, and a tin-containing raw material, and an oxygen-containing raw material in an alternate manner in order for the at least one raw material and the oxygen-containing raw material not to be mixed with each other.

Additional Statement 11

In the method of manufacturing the semiconductor device according to Additional Statement 3, preferably, the conductive oxide film is a zinc-containing oxide film or an indium-containing oxide film.

Additional Statement 12

In the method of manufacturing the semiconductor device according to Additional Statement 3, preferably, the gate insulating film or the capacitor insulating film is an oxide, the conductive oxide film has oxidation resistance, and in the forming of the electrode, the conductive oxide film is formed on a surface that comes into contact with the gate insulating film or the capacitor insulating film.

Additional Statement 13

In the method of manufacturing the semiconductor device according to Additional Statement 3, preferably, the gate insulating film or the capacitor insulating film is an insulating film that is formed of at least one oxide selected from the group consisting of HfSiOx, HfO₂, ZrO₂, TiO₂, Nb₂O₅, Ta₂O₅, SrTiO, BaSrTiO and PZT.

Additional Statement 14

In the method of manufacturing the semiconductor device according to Additional Statement 3, preferably, the electrode is a gallium zinc oxide (GZO) film.

Additional Statement 15

In the method of manufacturing a semiconductor device according to Additional Statement 3, preferably, the electrode including the conductive oxide film is formed after a laminated film, which has been formed in advance and which includes a film formed of the conductive oxide and a film formed of an additive for work function modulation, undergo thermal hysteresis.

Additional Statement 16

According to still another preferred aspect of the present invention, there is provided a method of manufacturing a semiconductor device, including:

loading a substrate to a processing chamber, a gate insulating film or a capacitor insulating film being formed on a surface of the substrate;

forming an electrode including a conductive oxide film selected from the group consisting of a molybdenum-containing oxide film, a tungsten-containing oxide film and a vanadium-containing oxide film on the substrate; and

unloading the substrate, on which the electrode is formed, from the processing chamber.

Additional Statement 17

According to still another preferred aspect of the present invention, there is provided a semiconductor device, including:

a gate insulating film or a capacitor insulating film that is formed on a substrate; and

an electrode including a conductive oxide film that is formed to come into contact with the gate insulating film or the capacitor insulating film,

wherein an additive that modulates a work function of the conductive oxide film is included in the conductive oxide film.

Additional Statement 18

In the semiconductor device according to Additional Statement 17, preferably, the conductive oxide film is a zinc-containing oxide film or an indium-containing oxide film.

Additional Statement 19

In the semiconductor device according to Additional Statement 17, preferably, the additive is at least one oxide film for addition that is selected from the group consisting of a gallium oxide film, an aluminum oxide film and a tin oxide film.

Additional Statement 20

In the semiconductor device according to Additional Statement 17, preferably, the electrode is a gallium zinc oxide (GZO) film.

Additional Statement 21

In the semiconductor device according to Additional Statement 17, preferably, the gate insulating film or the capacitor insulating film is an insulating film formed of an oxide.

Additional Statement 22

In the semiconductor device according to Additional Statement 21, preferably, the gate insulating film or the capacitor insulating film is an insulating film that is formed of at least one oxide selected from the group consisting of HfSiOx, HfO₂, ZrO₂, TiO₂, Nb₂O₅, Ta₂O₅, SrTiO, BaSrTiO and PZT.

Additional Statement 23

In the semiconductor device according to Additional Statement 21, preferably, the conductive oxide film includes an oxidation resistant film.

Additional Statement 24

In the semiconductor device according to Additional Statement 23, preferably, the oxidation resistant film is formed on a surface that comes into contact with the gate insulating film or the capacitor insulating film.

Additional Statement 25

In the semiconductor device according to Additional Statement 23, preferably, the conductive oxide film includes the oxidation resistant film and the additive.

Additional Statement 26

In the semiconductor device according to Additional Statement 23, preferably, the oxidation resistant film and the oxide film for addition are alternately laminated to form the conductive oxide film.

Additional Statement 27

In the semiconductor device according to Additional Statement 17, preferably, the conductive oxide film is a conductive oxide film that is obtained by oxidizing a metal of Mo, V, or W.

Additional Statement 28

According to still another preferred aspect of the present invention, there is provided a semiconductor device, including:

a gate electrode of a MOS (Metal Oxide Silicon) transistor, or a capacitor electrode of a DRAM (Dynamic Random Access Memory),

wherein a conductive oxide film is used for the gate electrode or the capacitor electrode.

Additional Statement 29

According to still another preferred aspect of the present invention, there is provided a semiconductor device, including:

a gate insulating film or a capacitor insulating film that is formed on a substrate; and

an electrode that includes a conductive oxide film, which is selected from the group consisting of a molybdenum-containing oxide film, a tungsten-containing oxide film and a vanadium-containing oxide film, and which is formed to come into contact with the gate insulating film or the capacitor insulating film.

Additional Statement 30

According to another preferred aspect of the present invention, there is provided a substrate processing apparatus, including:

a processing chamber that accommodates a substrate, a gate insulating film or a capacitor insulating film being formed on a surface of the substrate;

a raw material gas supply system that supplies plural raw material gases to the processing chamber; and

a controller that controls the raw material gas supply system to form an electrode, which includes a conductive oxide film to which an additive modulating a work function of the conductive oxide film is added, on the substrate by exposing the substrate to the plural raw material gases.

As stated above, although various typical embodiments of the present invention have been described, the present invention is not limited to these embodiments. Therefore, the invention is intended to be limited only by the appended claims.

What is claimed is:

1. A semiconductor device manufacturing method comprising:
loading a substrate to a processing chamber, a gate insulating film or a capacitor insulating film being formed on the substrate;
forming an electrode, which includes a conductive oxide film and to which an additive that modulates a work function of the conductive oxide film is added, on the substrate; and
unloading the substrate, on which the electrode is formed, from the processing chamber.

2. The semiconductor device manufacturing method according to claim 1, wherein in the forming of the electrode, the work function of the conductive oxide film is modulated by adding the additive to the conductive oxide film.

3. The semiconductor device manufacturing method according to claim 2, wherein in the forming of the electrode, the modulation of the work function of the conductive oxide film is controlled by controlling an amount of the additive with respect to the conductive oxide film so as to obtain a desired work function.

4. The semiconductor device manufacturing method according to claim 2, wherein the forming of the electrode includes;
forming the conductive oxide film on the substrate, and
adding the additive to the conductive oxide film that has been formed by the forming of the conductive oxide film.

5. The semiconductor device manufacturing method according to claim 4, wherein in the forming of the electrode, the forming of the conductive oxide film and the adding of the additive are alternately performed plural times.

6. The semiconductor device manufacturing method according to claim 4, wherein in the forming of the conductive oxide film, the conductive oxide film is formed by exposing the substrate to plural kinds of raw materials in an alternate manner in order for the plural kinds of raw materials not to be mixed with each other.

7. The semiconductor device manufacturing method according to claim 2, wherein the additive is at least one oxide film for addition that is selected from the group consisting of a gallium oxide film, an aluminum oxide film and a tin oxide film.

8. The semiconductor device manufacturing method according to claim 7, wherein in the adding of the additive, the oxide film for addition is formed by exposing the substrate to at least one raw material selected from the group consisting of a gallium-containing raw material, an aluminum-containing raw material and a tin-containing raw material, and an oxygen-containing raw material in an alternate manner in order for the at least one raw material and the oxygen-containing raw material not to be mixed with each other.

9. The semiconductor device manufacturing method according to claim 2, wherein the conductive oxide film is a zinc-containing oxide film or an indium-containing oxide film.

10. The semiconductor device manufacturing method according to claim 2, wherein the gate insulating film or the capacitor insulating film is an oxide, the conductive oxide film has oxidation resistance, and in the forming of the electrode, the conductive oxide film is formed on a surface that comes into contact with the gate insulating film or the capacitor insulating film.

11. The semiconductor device manufacturing method according to claim 2, wherein the gate insulating film or the capacitor insulating film is an insulating film that is formed of at least one oxide selected from the group consisting of HfSiOx, HfO₂, ZrO₂, TiO₂, Nb₂O₅, Ta₂O₅, SrTiO, BaSrTiO and PZT.

12. The semiconductor device manufacturing method according to claim 2, wherein the electrode is a gallium zinc oxide film.

13. The semiconductor device manufacturing method according to claim 2, wherein the electrode including the conductive oxide film is formed after a laminated film, which has been formed in advance and which includes a film formed of the conductive oxide and a film formed of an additive for work function modulation, undergo thermal hysteresis.

14. A semiconductor device, comprising:
a gate insulating film or a capacitor insulating film that is formed on a substrate; and
an electrode including a conductive oxide film that is formed to come into contact with the gate insulating film or the capacitor insulating film,
wherein an additive that modulates a work function of the conductive oxide film is included in the conductive oxide film.

15. The semiconductor device according to claim 14, wherein the conductive oxide film is a zinc-containing oxide film or an indium-containing oxide film.

16. The semiconductor device according to claim 14, wherein the gate insulating film or the capacitor insulating film is an insulating film formed of an oxide.

17. The semiconductor device according to claim 16, wherein the gate insulating film or the capacitor insulating film is an insulating film that is formed of at least one oxide selected from the group consisting of HfSiOx, HfO₂, ZrO₂, TiO₂, Nb₂O₅, Ta₂O₅, SrTiO, BaSrTiO and PZT.

18. The semiconductor device according to claim 16, wherein the conductive oxide film includes an oxidation resistant film.

19. The semiconductor device according to claim 18, wherein the conductive oxide film includes the oxidation resistant film and the additive.

20. A substrate processing apparatus, comprising:
a processing chamber that accommodates a substrate, a gate insulating film or a capacitor insulating film being formed on a surface of the substrate;
a raw material gas supply system that supplies plural raw material gases to the processing chamber; and
a controller that controls the raw material gas supply system to form an electrode, which includes a conductive oxide film to which an additive modulating a work function of the conductive oxide film is added, on the substrate by exposing the substrate to the plural raw material gases.
